(19) United States
(12) Patent Application Publication
(10) Pub. No.: US 2026/0255998 A1
(43) Pub. Date: Aug. 27, 2026

(54) SEMICONDUCTOR DEVICE AND METHOD OF MANUFACTURING SEMICONDUCTOR DEVICE

(71) Applicant: AOI ELECTRONICS CO., LTD., Takamatsu-shi, Kagawa (JP)

(72) Inventor: Takashi SUZUKI, Kagawa (JP)

(21) Appl. No.: 18/857,881

(22) PCT Filed: Mar. 20, 2023
(86) PCT No.: PCT/JP2023/010886

§ 371 Date: Oct. 18, 2024

(30) Foreign Application Priority Data
Apr. 21, 2022 (JP) 2022-070330

(51) Int. Cl. H10W 70/65; H10W 70/09; H10W 74/10; H10W 90/00; H10W 90/10

(52) U.S. Cl. CPC H10W 70/65; H10W 70/09; H10W 74/111; H10W 90/10; H10W 90/811

(57) ABSTRACT

A semiconductor device 1 includes a substrate 30 including a semiconductor chip 2 having a drain electrode 2D as a back electrode, a plurality of lead portions, and a sealing portion 31 that seals them and a wiring 56DH formed on a lower surface 30b of the substrate 30. The drain electrode 2D of the semiconductor chip 2 is exposed on the lower surface 30b of the substrate 30. The wiring 56DH is formed spanning over the sealing portion 31 and the drain electrode 2D of the semiconductor chip 2, and is in contact with the entire drain electrode 2D of the semiconductor chip 2.

### CROSS-REFERENCE TO RELATED APPLICATIONS

This application is a National Stage application of International Patent Application No. PCT/JP2023/010886, filed on Mar. 20, 2023, which claims priority to Japanese Patent Application No. 2022-070330, filed on Apr. 21, 2022, each of which is hereby incorporated by reference in its entirety.

### TECHNICAL FIELD

The present invention relates to a semiconductor device and a method of manufacturing a semiconductor device, and can be favorably used for, for example, a semiconductor device in which a semiconductor chip including a field effect transistor for switching is sealed and a method of manufacturing the same.

### BACKGROUND

As a power supply circuit, for example, a DC-DC converter has a configuration in which a power MOSFET for a high-side switch and a power MOSFET for a low-side switch are connected in series. For this reason, a semiconductor device in which a semiconductor chip in which a power MOSFET for a high-side switch is formed, a semiconductor chip in which a power MOSFET for a low-side switch is formed, and a semiconductor chip for controlling them are packaged together is used.

Japanese Unexamined Patent Application Publication No. 2018-85452 (Patent Document 1) describes a technique related to a semiconductor device in which a power element is sealed.

US Patent Application Publication No. US2018/0358326 (Patent Document 2) describes a technique related to a semiconductor device in which an electronic chip is sealed.

Patent Document 1: Japanese Unexamined Patent Application Publication No. 2018-85452

Patent Document 2: US Patent Application Publication No. US2018/0358326

### SUMMARY

### Problems to be Solved by the Invention

A semiconductor chip for switching has a front electrode and a back electrode located on opposite sides to each other, and a large current flows between the front electrode (source electrode) and the back electrode (drain electrode). In a semiconductor device including a semiconductor chip for switching, an external terminal that is electrically connected to a front electrode or a back electrode of the semiconductor chip for switching is provided, but if a connection resistance between the front electrode or the back electrode of the semiconductor chip for switching and the external terminal is high, the on-resistance may increase, which leads to the degradation of the performance of the semiconductor device.

### Means for Solving the Problems

According to one embodiment, a semiconductor device includes a substrate including a semiconductor chip, a plurality of lead portions, and a sealing portion that seals them and a wiring formed on a main surface of the substrate. One of a front electrode and a back electrode of the semiconductor chip is exposed on the main surface of the substrate. The wiring is formed spanning over the sealing portion and the one of the front electrode and the back electrode of the semiconductor chip, and is in contact with an entirety of the one of the front electrode and the back electrode of the semiconductor chip.

According to one embodiment, a method of manufacturing a semiconductor device includes (a) a step of disposing a lead frame on a sheet member and (b) a step of disposing a semiconductor chip on the sheet member such that a back electrode of the semiconductor chip faces the sheet member. The method of manufacturing the semiconductor device further includes (c) after the step (a) and the step (b), a step of forming a sealing portion that seals the semiconductor chip and a plurality of lead portions of the lead frame, on the sheet member, and the sealing portion has a first main surface that faces the sheet member and a second main surface on an opposite side of the first main surface. The method of manufacturing the semiconductor device further includes (d) after the step (c), a step of peeling off the sheet member from the sealing portion and (e) after the step (d), a step of forming a wiring electrically connected to the back electrode of the semiconductor chip, on a side of the first main surface of the sealing portion. The wiring is in contact with the entire back electrode of the semiconductor chip.

### Effects of the Invention

According to one embodiment, it is possible to improve the performance of the semiconductor device.

### BRIEF DESCRIPTIONS OF THE DRAWINGS

FIG. 1 is a circuit diagram illustrating a circuit configuration example of a semiconductor device according to an embodiment.

FIG. 2 is a top view of semiconductor chips used in the semiconductor device according to the embodiment.

FIG. 3 is a bottom view of the semiconductor chips used in the semiconductor device according to the embodiment.

FIG. 4 is a plan view illustrating the semiconductor device according to the embodiment in a manufacturing step.

FIG. 5 is a cross-sectional view illustrating the semiconductor device in the same manufacturing step as FIG. 4.

FIG. 6 is a cross-sectional view illustrating the semiconductor device in the same manufacturing step as FIG. 4.

FIG. 7 is a plan view illustrating the semiconductor device in a manufacturing step subsequent to FIG. 4 to FIG. 6.

FIG. 8 is a cross-sectional view illustrating the semiconductor device in the same manufacturing step as FIG. 7.

FIG. 9 is a cross-sectional view illustrating the semiconductor device in the same manufacturing step as FIG. 7.

FIG. 10 is a cross-sectional view illustrating the semiconductor device in the same manufacturing step as FIG. 7.

FIG. 11 is a cross-sectional view illustrating the semiconductor device in a manufacturing step subsequent to FIG. 7 to FIG. 10.

FIG. 12 is a cross-sectional view illustrating the semiconductor device in the same manufacturing step as FIG. 11.

FIG. 13 is a cross-sectional view illustrating the semiconductor device in a manufacturing step subsequent to FIG. 11 and FIG. 12.

FIG. 14 is a cross-sectional view illustrating the semiconductor device in the same manufacturing step as FIG. 13.

FIG. 15 is a cross-sectional view illustrating the semiconductor device in a manufacturing step subsequent to FIG. 13 and FIG. 14.

FIG. 16 is a cross-sectional view illustrating the semiconductor device in the same manufacturing step as FIG. 15.

FIG. 17 is a cross-sectional view illustrating the semiconductor device in a manufacturing step subsequent to FIG. 15 and FIG. 16.

FIG. 18 is a cross-sectional view illustrating the semiconductor device in the same manufacturing step as FIG. 17.

FIG. 19 is a cross-sectional view illustrating the semiconductor device in the same manufacturing step as FIG. 17.

FIG. 20 is a plan view illustrating the semiconductor device in the same manufacturing step as FIG. 17.

FIG. 21 is a cross-sectional view illustrating the semiconductor device in a manufacturing step subsequent to FIG. 17 to FIG. 20.

FIG. 22 is a cross-sectional view illustrating the semiconductor device in the same manufacturing step as FIG. 21.

FIG. 23 is a cross-sectional view illustrating the semiconductor device in a manufacturing step subsequent to FIG. 21 and FIG. 22.

FIG. 24 is a cross-sectional view illustrating the semiconductor device in the same manufacturing step as FIG. 23.

FIG. 25 is a cross-sectional view illustrating the semiconductor device in a manufacturing step subsequent to FIG. 23 and FIG. 24.

FIG. 26 is a cross-sectional view illustrating the semiconductor device in the same manufacturing step as FIG. 25.

FIG. 27 is a cross-sectional view illustrating the semiconductor device in the same manufacturing step as FIG. 26.

FIG. 28 is a plan view illustrating the semiconductor device in the same manufacturing step as FIG. 26.

FIG. 29 is a cross-sectional view illustrating the semiconductor device in a manufacturing step subsequent to FIG. 25 to FIG. 28.

FIG. 30 is a cross-sectional view illustrating the semiconductor device in the same manufacturing step as FIG. 29.

FIG. 31 is a cross-sectional view illustrating the semiconductor device in a manufacturing step subsequent to FIG. 29 and FIG. 30.

FIG. 32 is a cross-sectional view illustrating the semiconductor device in the same manufacturing step as FIG. 31.

FIG. 33 is a cross-sectional view illustrating the semiconductor device in a manufacturing step subsequent to FIG. 31 and FIG. 32.

FIG. 34 is a cross-sectional view illustrating the semiconductor device in the same manufacturing step as FIG. 33.

FIG. 35 is a cross-sectional view illustrating the semiconductor device in a manufacturing step subsequent to FIG. 33 and FIG. 34.

FIG. 36 is a cross-sectional view illustrating the semiconductor device in the same manufacturing step as FIG. 35.

FIG. 37 is a cross-sectional view illustrating the semiconductor device in a manufacturing step subsequent to FIG. 35 and FIG. 36.

FIG. 38 is a cross-sectional view illustrating the semiconductor device in the same manufacturing step as FIG. 37.

FIG. 39 is a cross-sectional view illustrating the semiconductor device in a manufacturing step subsequent to FIG. 37 and FIG. 38.

FIG. 40 is a cross-sectional view illustrating the semiconductor device in the same manufacturing step as FIG. 39.

FIG. 41 is a cross-sectional view illustrating the semiconductor device in the same manufacturing step as FIG. 39.

FIG. 42 is a plan view illustrating the semiconductor device in the same manufacturing step as FIG. 39.

FIG. 43 is a cross-sectional view illustrating the semiconductor device in a manufacturing step subsequent to FIG. 39 to FIG. 42.

FIG. 44 is a cross-sectional view illustrating the semiconductor device in the same manufacturing step as FIG. 43.

FIG. 45 is a cross-sectional view illustrating the semiconductor device in a manufacturing step subsequent to FIG. 43 and FIG. 44.

FIG. 46 is a cross-sectional view illustrating the semiconductor device in the same manufacturing step as FIG. 45.

FIG. 47 is a cross-sectional view illustrating the semiconductor device in a manufacturing step subsequent to FIG. 45 and FIG. 46.

FIG. 48 is a cross-sectional view illustrating the semiconductor device in the same manufacturing step as FIG. 47.

FIG. 49 is a cross-sectional view illustrating the semiconductor device in the same manufacturing step as FIG. 47.

FIG. 50 is a plan view illustrating the semiconductor device in the same manufacturing step as FIG. 47.

FIG. 51 is a cross-sectional view illustrating a semiconductor device according to another embodiment in a manufacturing step.

FIG. 52 is a cross-sectional view illustrating the semiconductor device in a manufacturing step subsequent to FIG. 51.

FIG. 53 is a cross-sectional view illustrating the semiconductor device in a manufacturing step subsequent to FIG. 52.

### DETAILED DESCRIPTION

Hereinafter, embodiments will be described in detail with reference to the drawings. In all of the drawings for describing the embodiments, members having the same function are denoted by the same reference characters and repetitive descriptions thereof will be omitted. Also, in the following embodiments, descriptions of the same or similar parts will not be repeated in principle unless particularly required.

In addition, the field effect transistor is described as a MOSFET (Metal Oxide Semiconductor Field Effect Transistor) in this application, but it does not exclude a non-oxide film as the gate insulating film.

### <Circuit Configuration>

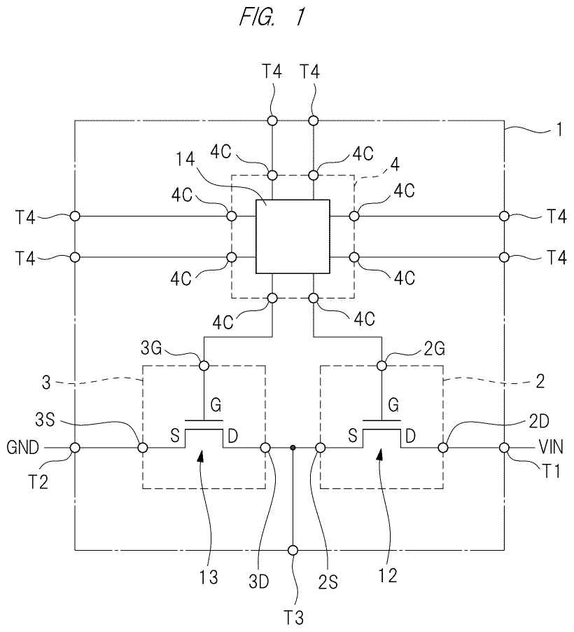

FIG. 1 is a circuit diagram illustrating a circuit configuration example of a semiconductor device (semiconductor package) 1 according to an embodiment of the present invention. The semiconductor device 1 can be used for, for example, a non-insulated DC-DC converter or an inverter. In FIG. 1, a part denoted by 1 and surrounded by a dash-dotted line corresponds to a circuit formed in the semiconductor device 1. In this part, a part denoted by 2 and surrounded by a dotted line is a part formed in a semiconductor chip 2, a part denoted by 3 and surrounded by a dotted line is a part formed in a semiconductor chip 3, and a part denoted by 4 and surrounded by a dotted line is a part formed in a semiconductor chip 4.

As illustrated in FIG. 1, the semiconductor device 1 includes the semiconductor chips 2, 3, and 4, and these three semiconductor chips 2, 3, and 4 are sealed in one package to form the semiconductor device 1. A power MOSFET 12 is formed in the semiconductor chip 2, a power MOSFET 13 is formed in the semiconductor chip 3, and a control circuit 14 is formed in the semiconductor chip 4. For example, trench-gate MOSFETs can be used as the power MOSFETs.

The semiconductor chip 2 has a source electrode 2S electrically connected to a source(S) of the power MOSFET 12 formed in the semiconductor chip 2, a drain electrode 2D electrically connected to a drain (D) of the power MOSFET 12 formed in the semiconductor chip 2, and a gate electrode 2G electrically connected to a gate (G) of the power MOSFET 12 formed in the semiconductor chip 2. Also, the semiconductor chip 3 has a source electrode 3S electrically connected to a source(S) of the power MOSFET 13 formed in the semiconductor chip 3, a drain electrode 3D electrically connected to a drain (D) of the power MOSFET 13 formed in the semiconductor chip 3, and a gate electrode 3G electrically connected to a gate (G) of the power MOSFET 13 formed in the semiconductor chip 3. Further, the semiconductor chip 4 has a plurality of electrodes 4C electrically connected to the control circuit 14 formed in the semiconductor chip 4.

The power MOSFET 12 is a field effect transistor for high-side switch (high potential side switch) and the power MOSFET 13 is a field effect transistor for low-side switch (low potential side switch).

The power MOSFET 12 and the power MOSFET 13 are connected in series between a terminal T1 and a terminal T2, the drain (D) of the power MOSFET 12 is connected to the terminal T1, the source(S) of the power MOSFET 12 is connected to the drain (D) of the power MOSFET 13, and the source(S) of the power MOSFET 13 is connected to the terminal T2.

Specifically, the drain electrode 2D of the semiconductor chip 2 is electrically connected to the terminal T1, the source electrode 2S of the semiconductor chip 2 is electrically connected to the drain electrode 3D of the semiconductor chip 3, and the source electrode 3S of the semiconductor chip 3 is electrically connected to the terminal T2. A terminal T3 is electrically connected to both the source electrode 2S of the semiconductor chip 2 and the drain electrode 3D of the semiconductor chip 3.

The terminals T1, T2, and T3 are external terminals (external connection terminals) of the semiconductor device 1. A power supply potential (VIN) is supplied to the terminal T1 from a power supply or the like outside the semiconductor device 1. A reference potential lower than the power supply potential, for example, a ground potential (GND), is supplied to the terminal T2. The terminal T3 is an output terminal. The terminal T3 is connected to, for example, a load provided outside the semiconductor device 1.

The gate electrode 2G of the semiconductor chip 2 is electrically connected to the electrode 4C of the semiconductor chip 4, and the gate electrode 3G of the semiconductor chip 3 is electrically connected to another electrode 4C of the semiconductor chip 4. The control circuit 14 formed in the semiconductor chip 4 includes a circuit (drive circuit) for controlling the operations of the power MOSFETs 12 and 13. The control circuit 14 can control the operations of the power MOSFETs 12 and 13 by controlling the gate voltages supplied from the electrodes 4C of the semiconductor chip 4 to the gate electrodes 2G and 3G of the semiconductor chips 2 and 3. Still another electrode 4C of the semiconductor chip 4 is electrically connected to a terminal T4. The terminal T4 is also an external terminal of the semiconductor device 1, and the control circuit 14 can be connected to a circuit outside the semiconductor device 1 through the terminal T4.

### <Structure and Manufacturing Process of Semiconductor Device>

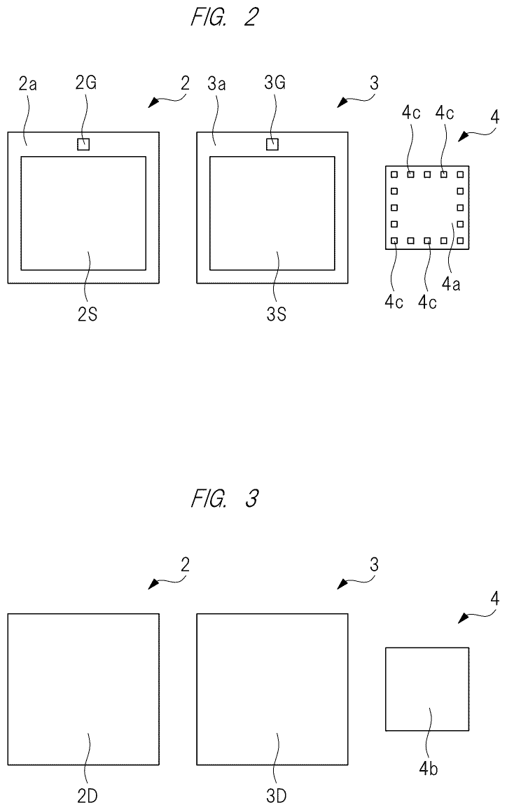

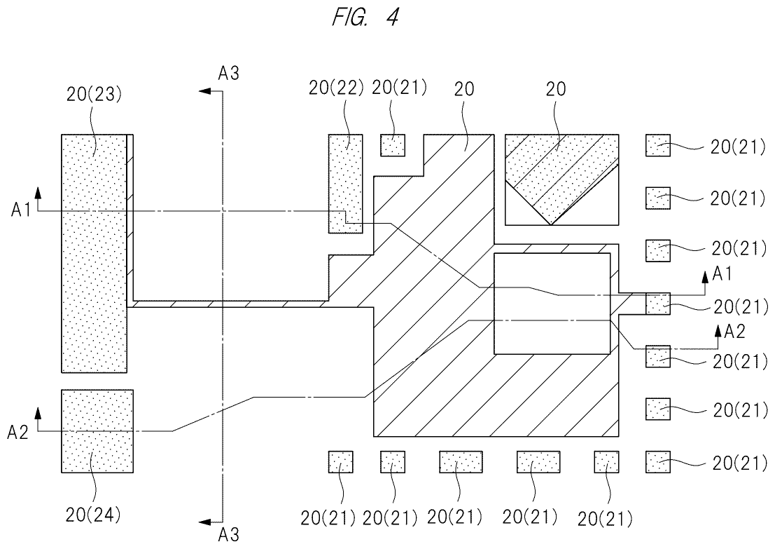

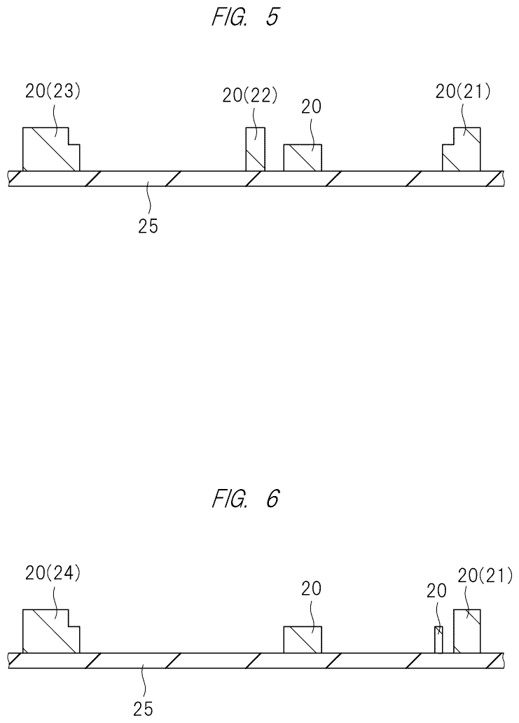

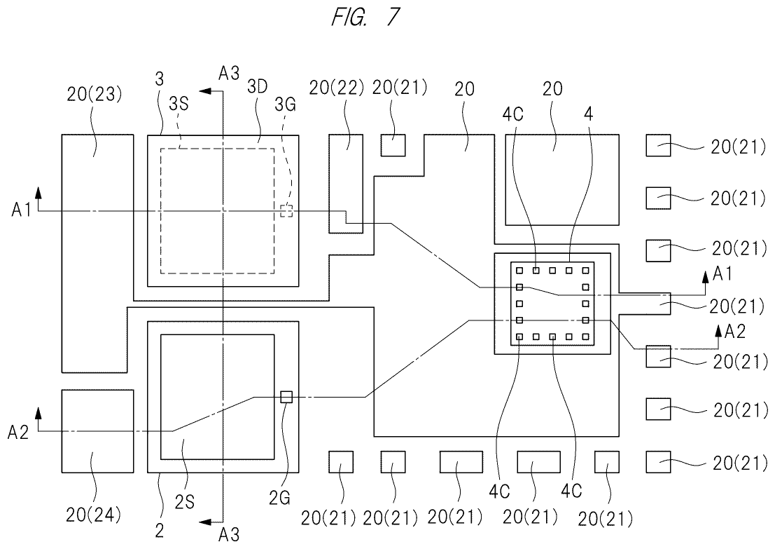

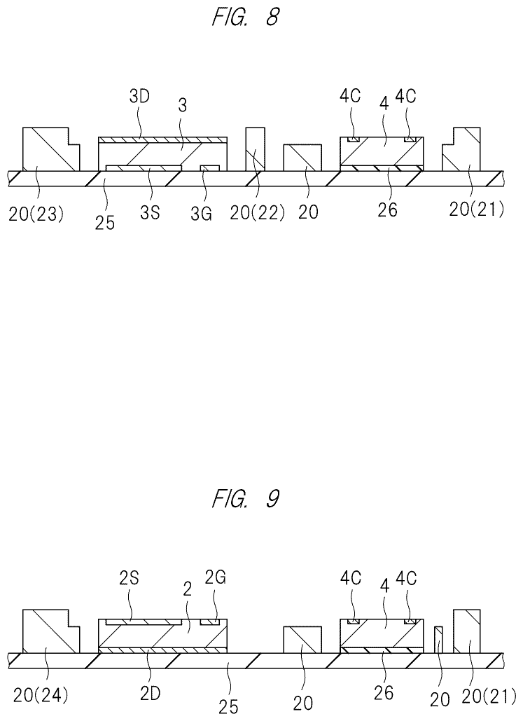

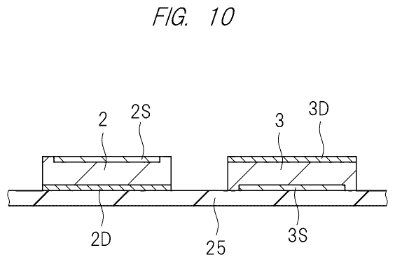

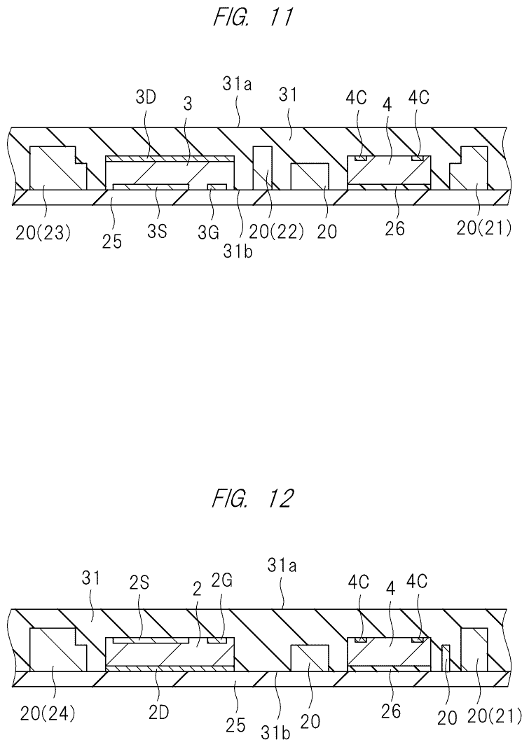

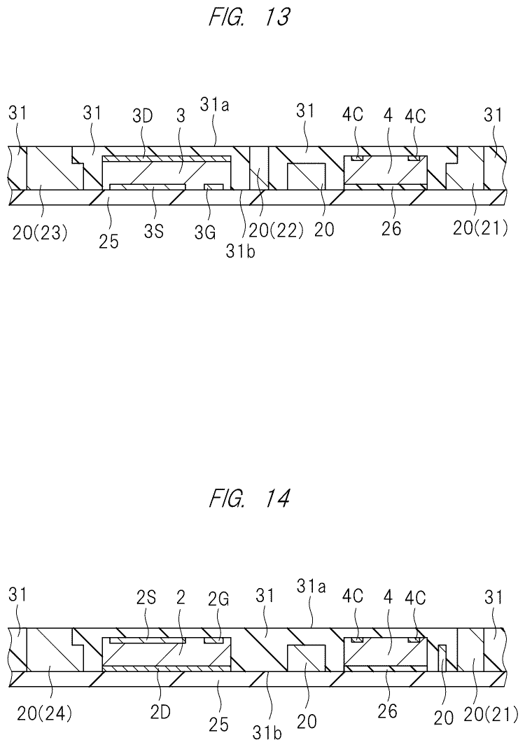

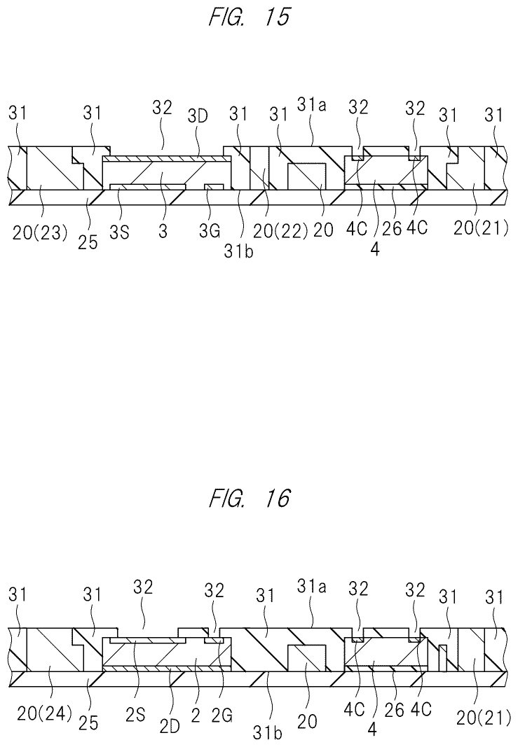

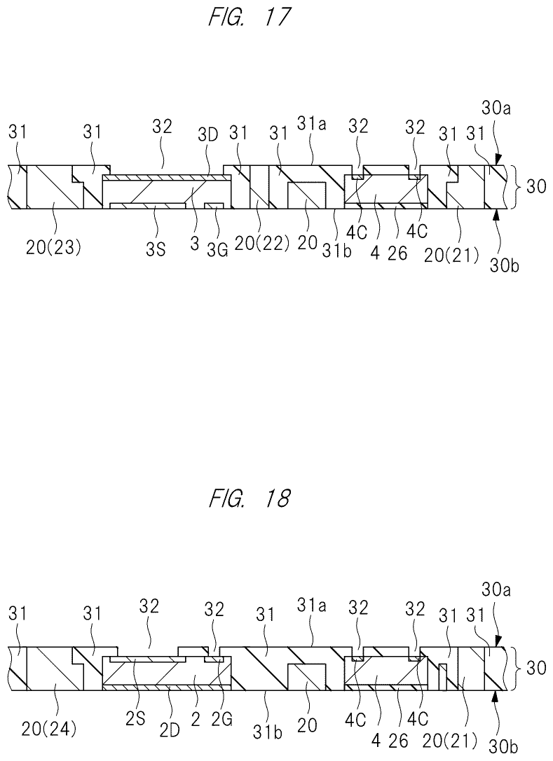

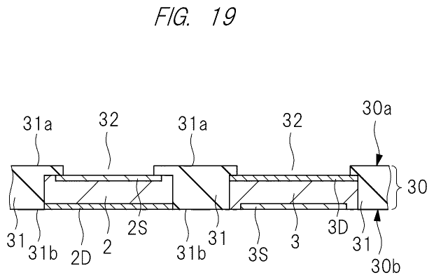

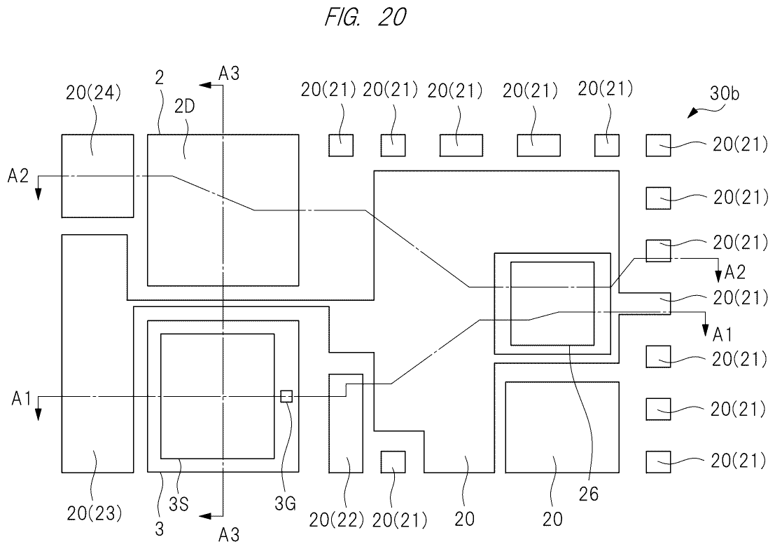

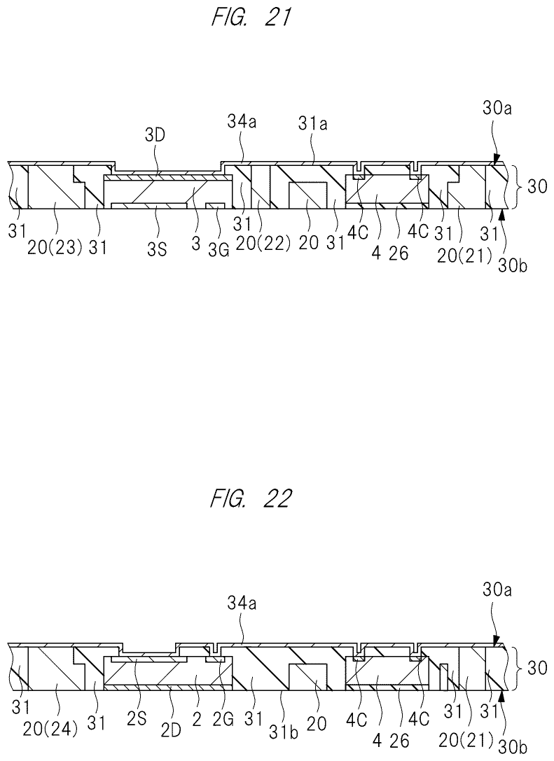

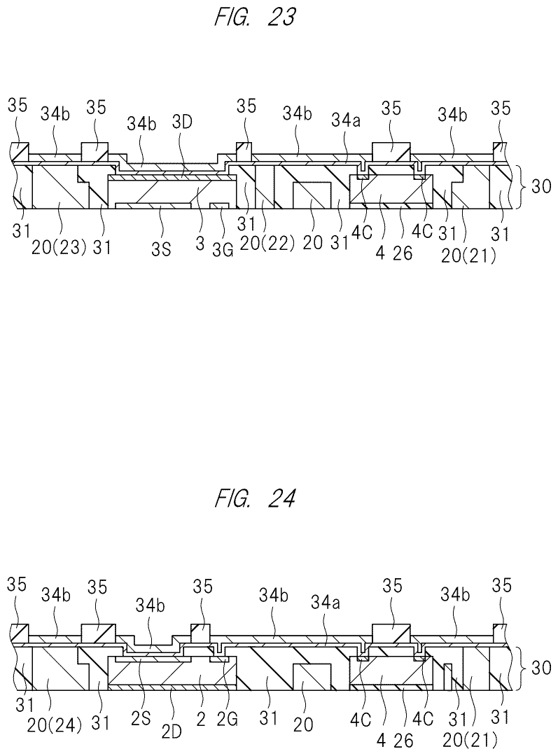

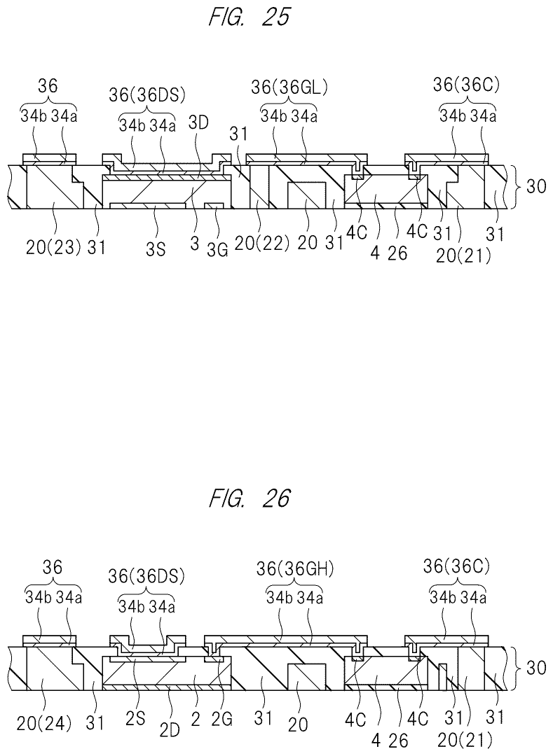

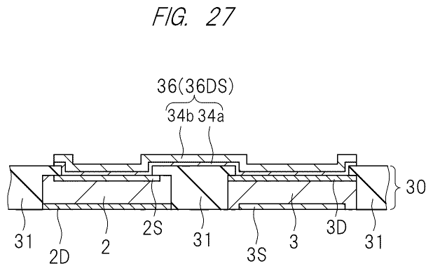

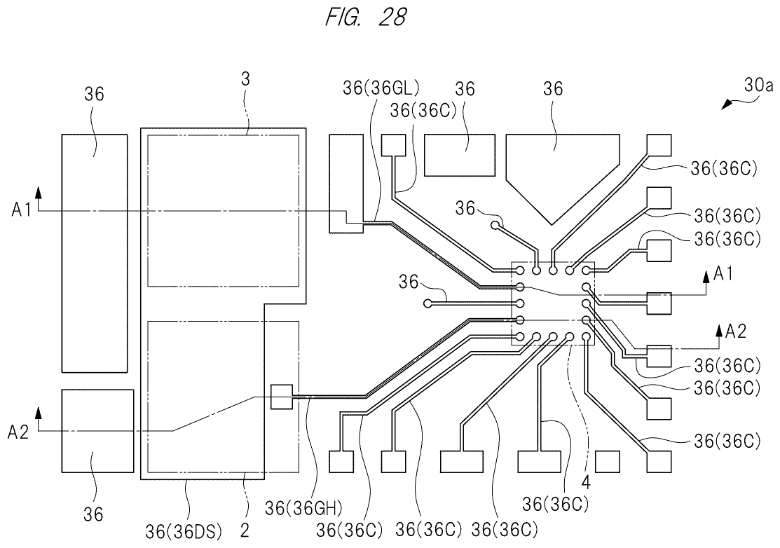

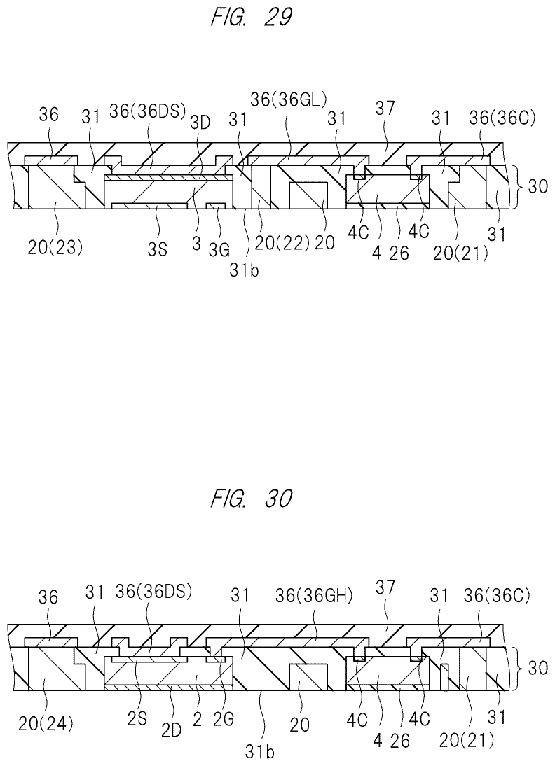

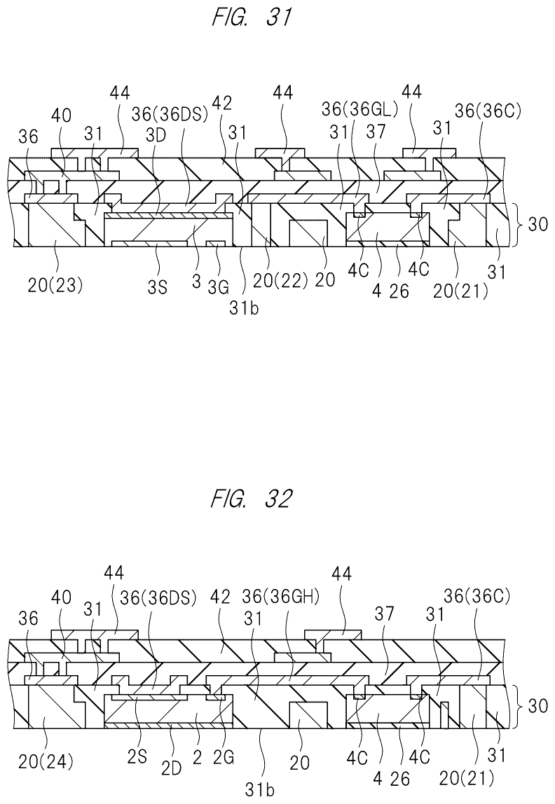

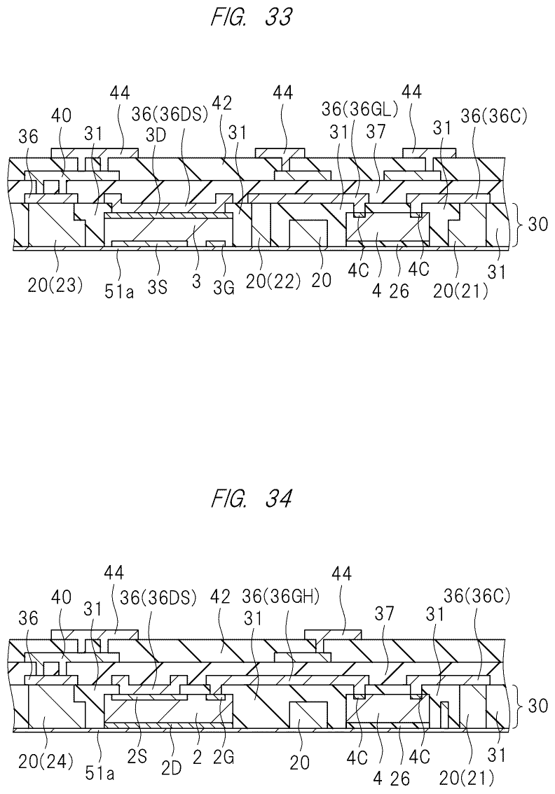

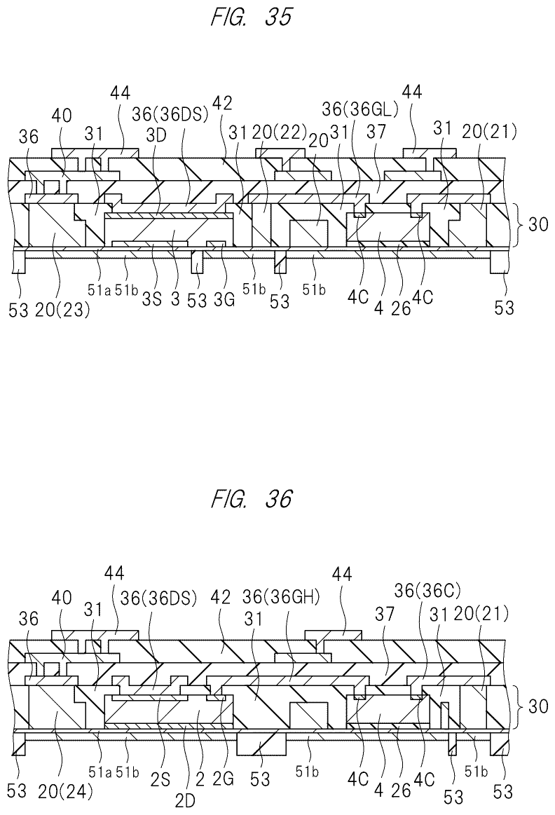

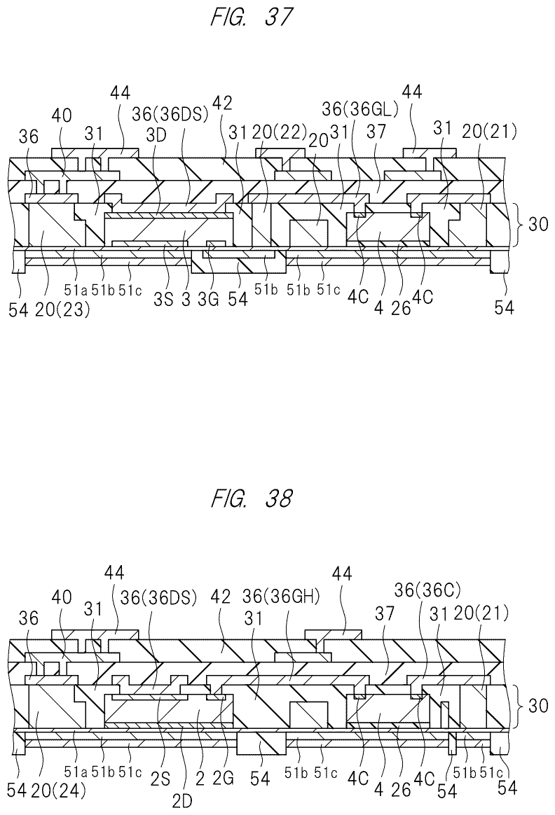

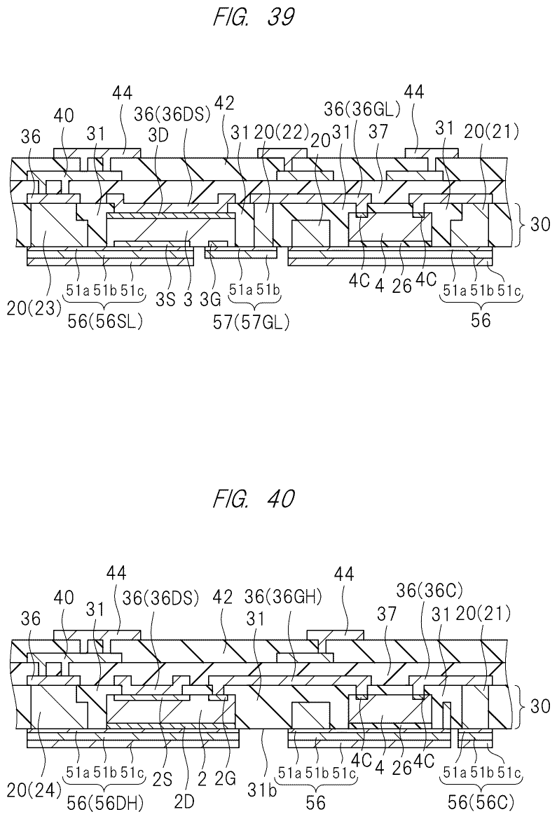

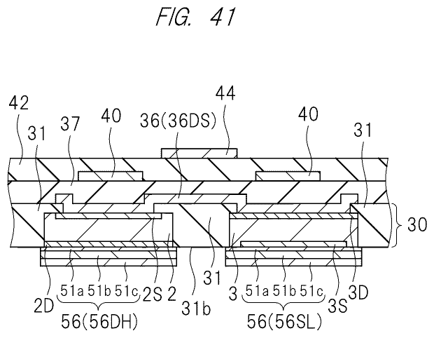

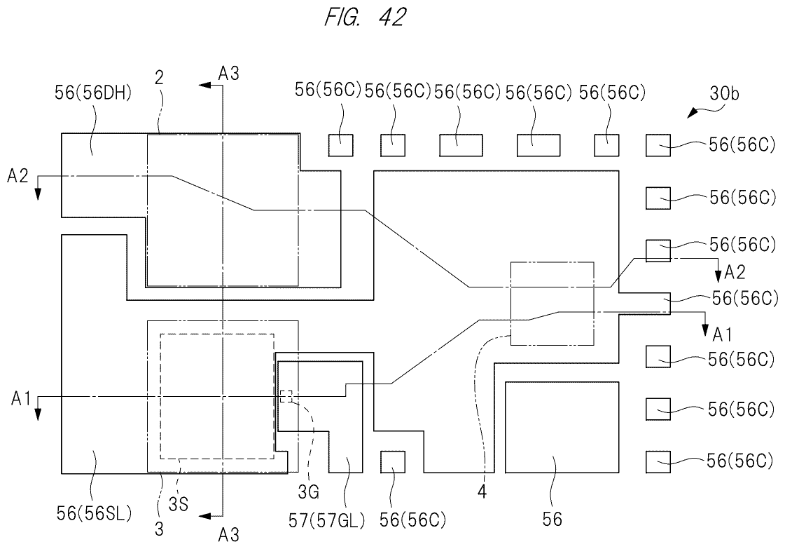

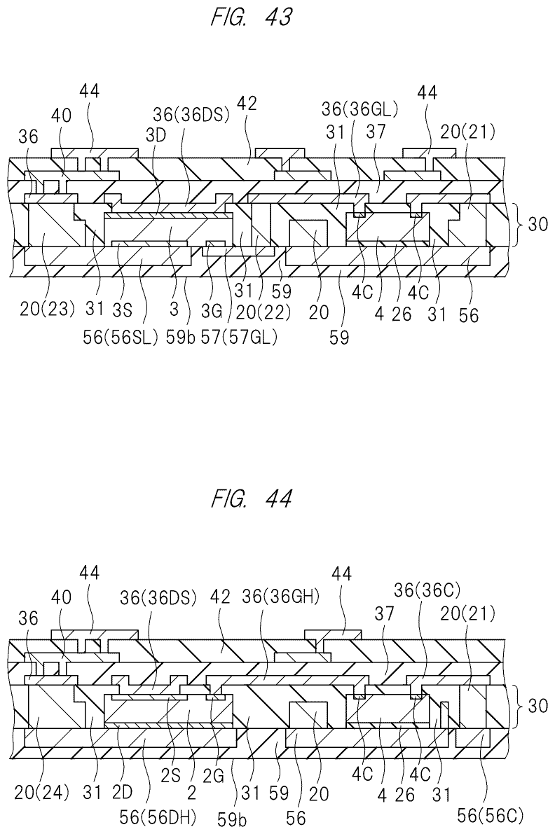

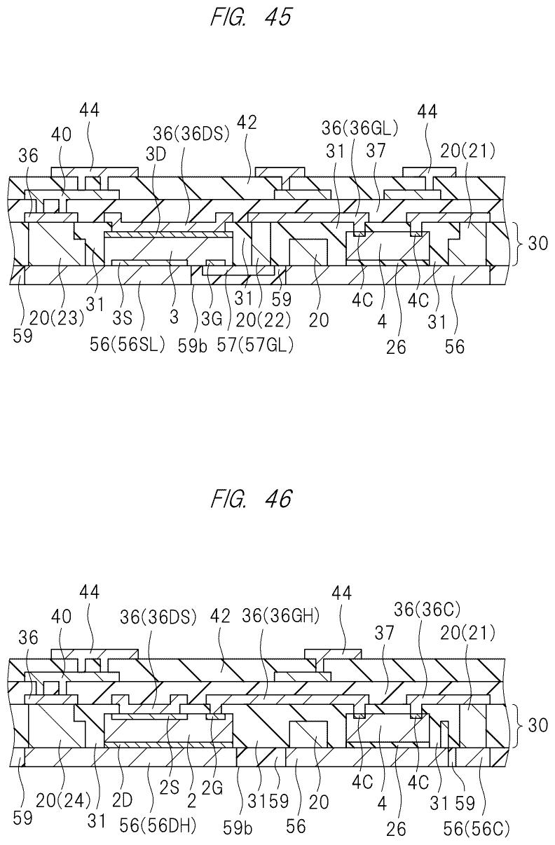

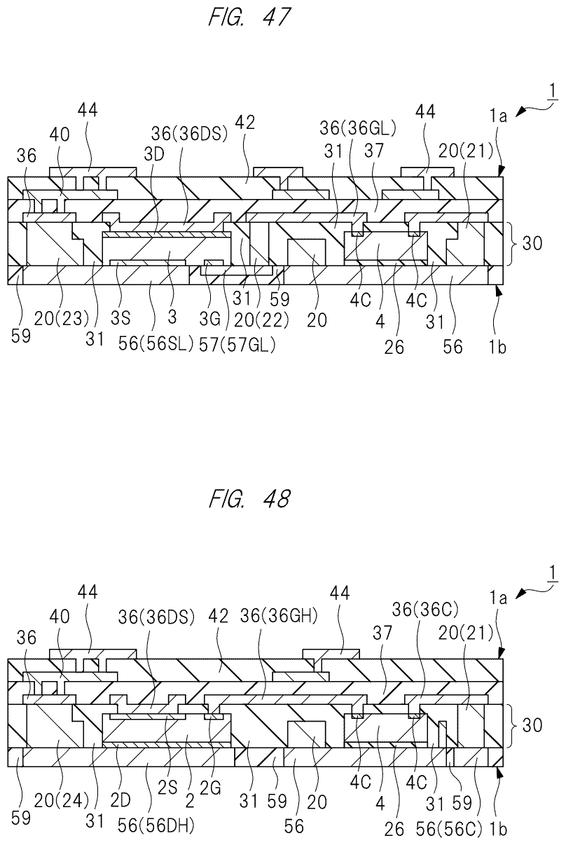

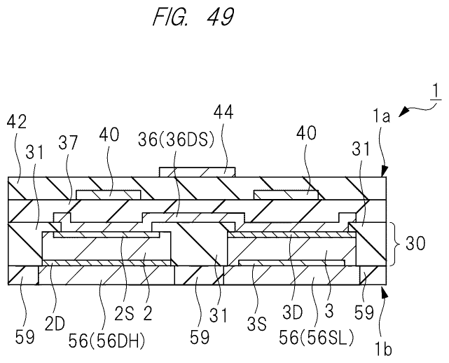

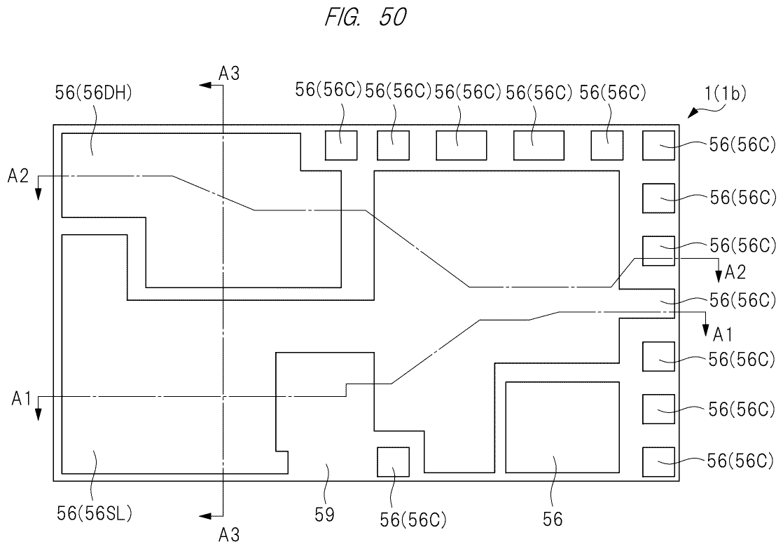

FIG. 2 is a top view of the semiconductor chips 2, 3, and 4 used in the semiconductor device 1 according to this embodiment, and FIG. 3 is a bottom view (back view) of the semiconductor chips 2, 3, and 4 used in the semiconductor device 1 according to this embodiment. FIG. 4 to FIG. 50 are cross-sectional views and plan views illustrating the manufacturing process of the semiconductor device 1 according to this embodiment. In FIG. 4 to FIG. 50, FIG. 4, FIG. 7, FIG. 20, FIG. 28, FIG. 42, and FIG. 50 are plan views illustrating each manufacturing step. Also, FIG. 5, FIG. 8, FIG. 11, FIG. 13, FIG. 15, FIG. 17, FIG. 21, FIG. 23, FIG. 25, FIG. 29, FIG. 31, FIG. 33, FIG. 35, FIG. 37, FIG. 39, FIG. 43, FIG. 45, and FIG. 47 are cross-sectional views at the position corresponding to a line A1-A1 in each manufacturing step. Further, FIG. 6, FIG. 9, FIG. 12, FIG. 14, FIG. 16, FIG. 18, FIG. 22, FIG. 24, FIG. 26, FIG. 30, FIG. 32, FIG. 34, FIG. 36, FIG. 38, FIG. 40, FIG. 44, FIG. 46, and FIG. 48 are cross-sectional views at the position corresponding to a line A2-A2 in each manufacturing step. Furthermore, FIG. 10, FIG. 19, FIG. 27, FIG. 41, and FIG. 49 are cross-sectional views at the position corresponding to a line A3-A3 in each manufacturing step. Note that the line A1-A1, the line A2-A2, and the line A3-A3 are illustrated in FIG. 4, FIG. 7, FIG. 20, FIG. 28, FIG. 42, and FIG. 50. Each drawing illustrates only one package, but a plurality of packages can be manufactured at the same time in a state where the plurality of packages is connected in a planar direction.

When manufacturing the semiconductor device 1, first, the semiconductor chip 2, the semiconductor chip 3, the semiconductor chip 4, a lead frame 20, and a back tape 25 are prepared. These may be prepared in any order or may be prepared at the same time.

Each of the semiconductor chips 2, 3, and 4 has a front surface which is one main surface and a back surface which is a main surface on the opposite side thereof, FIG. 2 illustrates the front surface side of the semiconductor chips 2, 3, and 4, and FIG. 3 illustrates the back surface side of the semiconductor chips 2, 3, and 4. In the semiconductor chip 2, the source electrode 2S and the gate electrode 2G are formed on the front surface side of the semiconductor chip 2, and the drain electrode 2D is formed on the back surface side of the semiconductor chip 2. Specifically, in the semiconductor chip 2, the source and gate electrodes 2S and 2G and the drain electrode 2D are formed on the surfaces on the opposite sides to each other, and are located on the opposite sides to each other. Each of the source electrode 2S and the gate electrode 2G is made of a conductive film exposed from an opening of an uppermost layer protective film 2a of the semiconductor chip 2. The source electrode 2S and the gate electrode 2G are front electrodes of the semiconductor chip 2, and the drain electrode 2D is a back electrode of the semiconductor chip 2 and is formed on the entire back surface of the semiconductor chip 2. Therefore, the back surface of the semiconductor chip 2 is made up of a surface of the drain electrode 2D. Similarly, in the semiconductor chip 3, the source electrode 3S and the gate electrode 3G are formed on the front surface side of the semiconductor chip 3, and the drain electrode 3D is formed on the back surface side of the semiconductor chip 3. Specifically, in the semiconductor chip 3, the source and gate electrodes 3S and 3G and the drain electrode 3D are formed on the surfaces on the opposite sides to each other, and are located on the opposite sides to each other. Each of the source electrode 3S and the gate electrode 3G is made of a conductive film exposed from an opening of an uppermost layer protective film 3a of the semiconductor chip 3. The source electrode 3S and the gate electrode 3G are front electrodes of the semiconductor chip 3, and the drain electrode 3D is a back electrode of the semiconductor chip 3 and is formed on the entire back surface of the semiconductor chip 3. Therefore, the back surface of the semiconductor chip 3 is made up of a surface of the drain electrode 3D. In the semiconductor chip 4, the plurality of electrodes 4C is formed on the front surface side of the semiconductor chip 4. Each of the electrodes 4C is made of a conductive film exposed from an opening of an uppermost layer protective film 4a of the semiconductor chip 4. No electrode (back electrode) is formed on the back surface of the semiconductor chip 4. Therefore, the back surface of the semiconductor chip 4 is made up of a back surface of a semiconductor substrate constituting the semiconductor chip 4. In addition, a metal layer may be formed in advance on each electrode of the semiconductor chips 2, 3, and 4 such that the electrodes can be easily connected to a plating layer to be formed in a latter step, and the metal layer can also be regarded as a part of each electrode in that case.

Next, as illustrated in FIG. 4 to FIG. 6, the lead frame 20 is disposed (mounted) on the back tape 25.

The lead frame 20 includes lead portions (conductor portions, terminal portions) 21, 22, 23, and 24. The lead frame 20 is made of a conductor, preferably, a metal material such as copper (Cu) or a copper alloy (for example, copper alloy containing nickel). The lead portions 21, 22, 23, and 24 can be regarded as conductor portions. In each drawing, illustration of a frame of the lead frame 20 is omitted for simplification.

The back tape 25 is a sheet-shaped (film-shaped) member and is made of, for example, an insulating film such as a polyimide film. Therefore, the back tape 25 can be regarded as a sheet member (film member). The back tape 25 has an adhesive layer (adhesion layer, sticky layer) on the surface on which the semiconductor chips 2, 3, and 4 and the lead frame 20 are disposed. A lower surface of the lead frame 20 comes into contact with the adhesive layer of the back tape 25, whereby the lead frame 20 is fixed to the back tape 25.

Although FIG. 4 is a plan view, the lead frame 20 is hatched with dots and diagonal lines for ease of understanding. Of these, the region hatched with diagonal lines is subjected to half-etching performed from the upper surface side, and thus has a smaller thickness than the region hatched with dots.

Next, as illustrated in FIG. 7 to FIG. 10, the semiconductor chips 2, 3, and 4 are disposed (mounted) on the back tape 25.

When disposing the semiconductor chip 2 and the semiconductor chip 3 on the back tape 25, up-down (front-back) orientations thereof are opposite to each other. Specifically, the semiconductor chip 2 is disposed on the back tape 25 such that the source electrode 2S and the gate electrode 2G face upward and the drain electrode 2D faces the back tape 25. Therefore, the semiconductor chip 2 is disposed on and fixed to the back tape 25 in a state where the drain electrode 2D serving as a back electrode is in contact with the adhesive layer of the back tape 25. On the other hand, the semiconductor chip 3 is disposed on the back tape 25 such that the drain electrode 3D faces upward and the source electrode 3S and the gate electrode 3G face the back tape 25. Therefore, the semiconductor chip 3 is disposed on and fixed to the back tape 25 in a state where the protective film on the front surface side (uppermost layer protective film of the semiconductor chip 3) is in contact with the adhesive layer of the back tape 25.

The semiconductor chip 4 is disposed on and fixed to the back tape 25 such that the front surface side faces upward and the back surface of the semiconductor chip 4 faces the back tape 25. Also, the semiconductor chip 4 can be disposed on and fixed to the back tape 25 via a DAF (Die Attach Film) 26 by attaching the DAF 26 on the back surface of the semiconductor chip 4 in advance. In this case, the DAF 26 is interposed between the back surface of the semiconductor chip 4 and the back tape 25, and FIG. 8 and FIG. 9 illustrate this case.

Furthermore, if the adhesive layer of the back tape 25 rises up onto side surfaces of the semiconductor chips 2, 3, and 4 when the semiconductor chips 2, 3, and 4 are mounted on the back tape 25, the raised portions of the adhesive layer may be removed by a plasma cleaning process. This makes it possible to prevent the occurrence of insufficient filling of a sealing portion 31 caused by the raised portion of the adhesive layer of the back tape 25 when the sealing portion 31 is formed later.

Either the step of mounting the lead frame 20 on the back tape 25 or the step of mounting the semiconductor chips 2, 3, and 4 on the back tape 25 may be performed first, but it is more preferable that the step of mounting the lead frame 20 is performed first. This makes it easier to perform the step of mounting the lead frame 20 on the back tape 25 and the step of mounting the semiconductor chips 2, 3, and 4 on the back tape 25.

Next, as illustrated in FIG. 11 and FIG. 12, the sealing portion (sealing resin portion) 31 that seals the semiconductor chips 2, 3, and 4 and the lead frame 20 is formed. The sealing portion 31 has an upper surface 31a and a lower surface 31b located on the opposite sides to each other. The sealing portion 31 is made of, for example, an insulating resin material such as a thermosetting resin. At this stage, the semiconductor chips 2, 3, and 4 and the electrodes 2S, 2G, 3D, and 4C thereof are covered with the sealing portion 31. Therefore, on the upper surface 31a of the sealing portion 31, the semiconductor chips 2, 3, and 4 and the electrodes 2S, 2G, 3D, and 4C thereof are not exposed, and the lead portions 21, 22, 23, and 24 of the lead frame 20 are also not exposed. Also, since the lower surface side of the lead frame 20, the back surface side of the semiconductor chips 2 and 4, and the front surface side of the semiconductor chip 3 are fixed to the back tape 25, the sealing portion 31 is not formed on the lower surface of the lead frame 20, on the back surfaces of the semiconductor chips 2 and 4, and on the front surface of the semiconductor chip 3. Therefore, the lower surfaces of the lead portions 21, 22, 23, and 24 of the lead frame 20, the back surface of the semiconductor chip 2 (that is, surface of the drain electrode 2D), the front surface of the semiconductor chip 3, and the lower surface of the DAF 26 are flush with the lower surface 31b of the sealing portion 31.

Next, as illustrated in FIG. 13 and FIG. 14, the upper surface 31a of the sealing portion 31 is polished to reduce the thickness of the sealing portion 31. At this time, the sealing portion 31 is polished until the upper surfaces of the lead portions 21, 22, 23, and 24 of the lead frame 20 are exposed from the upper surface 31a of the sealing portion 31, so that the upper surfaces of the lead portions 21, 22, 23, and 24 of the lead frame 20 are exposed from the upper surface 31a of the sealing portion 31. Therefore, at the stage of FIG. 13 and FIG. 14 (the stage where the polishing of the sealing portion 31 is finished), the state in which the region of the lead frame 20 in FIG. 4 above hatched with dots is exposed on the upper surface of the sealing portion 31 and the region thereof hatched with diagonal lines is not exposed on the upper surface of the sealing portion 31 is maintained. Also, at the stage of FIG. 13 and FIG. 14, the semiconductor chips 2, 3, and 4 and the electrodes 2S, 2G, 3D, and 4C thereof are not exposed from the upper surface 31a of the sealing portion 31.

In this manner, a substrate 30 in which the semiconductor chips 2, 3, and 4 are sealed is formed. The substrate 30 includes the semiconductor chips 2, 3, and 4, the lead portions 21, 22, 23, and 24 of the lead frame 20, and the sealing portion 31 that seals them. The substrate 30 has an upper surface (main surface) 30a and a lower surface (main surface) 30b located on the opposite sides to each other. The upper surface 30a of the substrate 30 is made up of the upper surface 31a of the sealing portion 31 and the upper surface of the lead frame 20 (lead portions 21, 22, 23, and 24), and the lower surface 30b of the substrate 30 is made up of the lower surface 31b of the sealing portion 31, the lower surface of the lead frame 20 (lead portions 21, 22, 23, and 24), the back surface of the semiconductor chip 2 (the surface of the drain electrode 2D), and the front surface of the semiconductor chip 3. On the lower surface 30b of the substrate 30, the lower surface 31b of the sealing portion 31 and the back surface of the semiconductor chip 2 (that is, the surface of the drain electrode 2D) are located on the same plane. Also, on the lower surface 30b of the substrate 30, the lower surface 31b of the sealing portion 31 and the front surface of the semiconductor chip 3 (that is, the surface of the uppermost layer protective film 3a constituting the semiconductor chip 3) are located on the same plane.

Next, as illustrated in FIG. 15 and FIG. 16, openings (holes) 32 are formed in the sealing portion 31 by, for example, laser processing. At this time, a laser is irradiated from the side of the upper surface 30a of the substrate 30 onto the regions of the upper surface 31a of the sealing portion 31 where the openings 32 are to be formed. The openings 32 are formed on the source electrode 2S and the gate electrode 2G of the semiconductor chip 2, on the drain electrode 3D of the semiconductor chip 3, and on the plurality of electrodes 4C of the semiconductor chip 4, respectively. At the bottom of each opening 32, the source electrode 2S of the semiconductor chip 2, the gate electrode 2G of the semiconductor chip 2, the drain electrode 3D of the semiconductor chip 3, and the electrode 4C of the semiconductor chip 4 are exposed. As a result, on the upper surface 30a of the substrate 30, the source electrode 2S and the gate electrode 2G of the semiconductor chip 2, the drain electrode 3D of the semiconductor chip 3, and the electrode 4C of the semiconductor chip 4 are exposed from the sealing portion 31.

Next, as illustrated in FIG. 17 to FIG. 19, the back tape 25 is peeled off (ripped off) from the lower surface 30b of the substrate 30. FIG. 20 is a plan view illustrating the side of the lower surface 30b of the substrate 30 after the back tape 25 has been peeled off. When the back tape 25 has been peeled off, the lower surface 30b of the substrate 30 is exposed. Specifically, the lower surface 31b of the sealing portion 31, the lower surface of the lead frame 20 (lead portions 21, 22, 23, and 24), the back surface (drain electrode 2D) of the semiconductor chip 2, the front surface (source electrode 3S and gate electrode 3G) of the semiconductor chip 3, and the lower surface of the DAF 26 are exposed.

In the case where the semiconductor chip 4 is mounted directly on the back tape 25 without using the DAF 26, the back surface of the semiconductor chip 4 is exposed instead of the lower surface of the DAF 26 when the back tape 25 is peeled off from the lower surface 30b of the substrate 30.

Next, as illustrated in FIG. 21 and FIG. 22, a seed layer (metal layer) 34a is formed on the upper surface 30a of the substrate 30. The seed layer 34a can be formed by using, for example, the electroless plating. Therefore, for example, an electroless copper plating layer can be used as the seed layer 34a.

The seed layer 34a is formed on the entire upper surface 30a of the substrate 30.

Specifically, the seed layer 34a is continuously formed on the upper surface 31a of the sealing portion 31, on the source electrode 2S, the gate electrode 2G, the drain electrode 3D, and the electrode 4C exposed from the openings 32, and on the upper surfaces of the lead portions 21, 22, 23, and 24 of the lead frame 20 exposed from the upper surface 31a of the sealing portion 31.

Next, as illustrated in FIG. 23 and FIG. 24, a resist pattern 35 is formed on the seed layer 34a. The resist pattern 35 can be formed by, for example, attaching a photoresist film onto the seed layer 34a and then exposing and developing the photoresist film.

Next, a metal layer (electrolytic plating layer) 34b is formed by the electrolytic plating on a part of the seed layer 34a exposed without being covered with the resist pattern 35. The metal layer 34b is preferably a copper layer (copper plating layer). Thereafter, the resist pattern 35 is removed, and a part of the seed layer 34a exposed without being covered with the metal layer 34b is removed by etching or the like. FIG. 25 to FIG. 27 illustrate this stage. As a result, a wiring (wiring layer) 36 made up of a stacked film of the seed layer 34a and the metal layer (electrolytic plating layer) 34b on the seed layer 34a is formed on the upper surface 30a of the substrate 30. FIG. 28 is a plan view illustrating the side of the upper surface 30a of the substrate 30 at the stage of FIG. 25 to FIG. 27, in which the wiring 36 has been formed and the positions of the semiconductor chips 2, 3, and 4 are indicated by two-dot dashed lines. The wiring 36 includes a wiring 36DS, a wiring 36GH, a wiring 36GL, and a plurality of wirings 36C.

The wiring 36DS is a wiring for electrically connecting the source electrode 2S of the semiconductor chip 2 and the drain electrode 3D of the semiconductor chip 3. The wiring 36DS integrally includes a portion located on the source electrode 2S of the semiconductor chip 2 and electrically connected to the source electrode 2S, a portion located on the drain electrode 3D of the semiconductor chip 3 and electrically connected to the drain electrode 3D, and a portion connecting them. As a result, the source electrode 2S of the semiconductor chip 2 and the drain electrode 3D of the semiconductor chip 3 are electrically connected through the wiring 36DS.

The wiring 36GH is a wiring for electrically connecting the gate electrode 2G of the semiconductor chip 2 and the electrode 4C of the semiconductor chip 4. One end of the wiring 36GH is located on the gate electrode 2G of the semiconductor chip 2 and is electrically connected to the gate electrode 2G, and the other end of the wiring 36GH is located on the electrode 4C of the semiconductor chip 4 and is electrically connected to the electrode 4C. As a result, the gate electrode 2G of the semiconductor chip 2 and the electrode 4C of the semiconductor chip 4 are electrically connected through the wiring 36GH.

The wiring 36GL is a wiring for electrically connecting the gate electrode 3G of the semiconductor chip 3 and the electrode 4C of the semiconductor chip 4. One end of the wiring 36GL is located on the lead portion (gate connection conductor portion) 22 and is electrically connected to the lead portion 22, and the other end of the wiring 36GL is located on the electrode 4C of the semiconductor chip 4 and is electrically connected to the electrode 4C. The gate electrode 3G of the semiconductor chip 3 and the lead portion 22 are electrically connected through a wiring 57GL to be formed later. As a result, the gate electrode 3G of the semiconductor chip 3 and the electrode 4C of the semiconductor chip 4 are electrically connected through the wiring 36GL, the lead portion 22, and the wiring 57GL to be formed later.

The wiring 36C is a wiring for electrically connecting the lead portion 21 and the electrode 4C of the semiconductor chip 4. One end of the wiring 36C is located on the lead portion 21 and is electrically connected to the lead portion 21, and the other end of the wiring 36C is located on the electrode 4C of the semiconductor chip 4 and is electrically connected to the electrode 4C. As a result, the electrode 4C of the semiconductor chip 4 and the lead portion 21 are electrically connected through the wiring 36C.

The wiring 36 is formed also on the lead portions 23 and 24.

Next, as illustrated in FIG. 29 and FIG. 30, an insulating layer 37 is formed on the upper surface 31a of the sealing portion 31 so as to cover the wiring 36. The insulating layer 37 is made of an insulating resin material such as a thermosetting resin. In FIG. 29 and FIG. 30 and the following drawings, the seed layer 34a and the metal layer 34b constituting the wiring 36 are not illustrated separately but are illustrated integrally for simplification.

Next, as illustrated in FIG. 31 and FIG. 32, an opening that exposes a part of the wiring 36 is formed in the insulating layer 37 by, for example, laser processing.

Next, a wiring (wiring layer) 40 is formed on the insulating layer 37. Since the method of forming the wiring 40 is basically the same as the method of forming the wiring 36, the repetitive description thereof will be omitted here. The wiring 40 is electrically connected to the wiring 36 exposed from the opening of the insulating layer 37.

Next, an insulating layer 42 is formed on the upper surface of the insulating layer 37 so as to cover the wiring 40. The insulating layer 42 can be formed of the same material as the insulating layer 37. Then, an opening that exposes a part of the wiring 40 is formed in the insulating layer 42 by, for example, laser processing. Further, a wiring (wiring layer) 44 is formed on the insulating layer 42 by the same method as that for the wirings 36 and 40. FIG. 31 and FIG. 32 illustrate this stage. The wiring 44 is electrically connected to the wiring 40 exposed from the opening of the insulating layer 42.

Next, as illustrated in FIG. 33 and FIG. 34, a seed layer (metal layer) 51a is formed on the lower surface 30b of the substrate 30. The seed layer 51a can be formed by using, for example, the electroless plating. Therefore, for example, an electroless copper plating layer can be used as the seed layer 51a.

The seed layer 51a is formed on the entire lower surface 30b of the substrate 30. Specifically, the seed layer 51a is continuously formed on the lower surface 31b of the sealing portion 31, on the lower surface of the lead frame 20 (lead portions 21, 22, 23, and 24), on the back surface of the semiconductor chip 2 (that is, on the drain electrode 3D), on the front surface of the semiconductor chip 3 (including the surfaces of the source electrode 3S and the gate electrode 3G), and on the lower surface of the DAF 26.

Next, as illustrated in FIG. 35 and FIG. 36, a resist pattern 53 is formed on the seed layer 51a by the same method as that for the resist pattern 35.

Next, a metal layer (electrolytic plating layer) 51b is formed by the electrolytic plating on a part of the seed layer 51a exposed without being covered with the resist pattern 53. The metal layer 51b is preferably a copper layer (copper plating layer). FIG. 35 and FIG. 36 illustrate this stage.

Next, after removing the resist pattern 53, a resist pattern 54 is formed on the seed layer 51a by the same method as that for the resist pattern 53 as illustrated in FIG. 37 and FIG. 38. The resist pattern 54 has an opening that exposes the metal layer 51b, but a part of the metal layer 51b is covered with the resist pattern 54.

Next, a metal layer (electrolytic plating layer) 51c is formed by the electrolytic plating on a part of the metal layer 51b exposed without being covered with the resist pattern 54. The metal layer 51c is preferably a copper layer (copper plating layer). FIG. 37 and FIG. 38 illustrate this stage.

Next, after removing the resist pattern 54, a part of the seed layer 51a exposed without being covered with the metal layers 51b and 51c is removed by etching or the like. FIG. 39 to FIG. 41 illustrate this stage. As a result, a wiring (wiring layer) 56 made up of a stacked film of the seed layer 51a, the metal layer (electrolytic plating layer) 51b on the seed layer 51a, and the metal layer (electrolytic plating layer) 51c on the metal layer 51b and a wiring (wiring layer) 57 made up of a stacked film of the seed layer 51a and the metal layer (electrolytic plating layer) 51b on the seed layer 51a are formed on the lower surface 30b of the substrate 30. The metal layer 51c is formed on the metal layer 51b constituting the wiring 56, but the metal layer 51c is not formed on the metal layer 51b constituting the wiring 57. The thickness of the wiring 56 made up of the three layers of the seed layer 51a, the metal layer 51b, and the metal layer 51c is larger than the thickness of the wiring 57 made up of the two layers of the seed layer 51a and the metal layer 51b. FIG. 42 is a plan view illustrating the side of the lower surface 30b of the substrate 30 at the stage of FIG. 39 to FIG. 41, in which the wiring 56 is illustrated, the positions of the semiconductor chips 2, 3, and 4 are indicated by two-dot dashed lines, and the positions of the source electrode 3S and the gate electrode 3G of the semiconductor chip 3 are indicated by dotted lines.

In this embodiment, the thick wiring 56 and the wiring 57 that is thinner than the wiring 56 are formed on the lower surface 30b of the substrate 30. As another embodiment, it is also possible to make the wiring 56 and the wiring 57 have the same thickness. In this case, the resist pattern 54 and the metal layer 51c are not formed, and a part of the seed layer 51a exposed without being covered with the metal layer 51b may be removed by etching or the like after removing the resist pattern 53. As a result, both the wiring 56 and the wiring 57 are made up of the two layers of the seed layer 51a and the metal layer 51b, and the wiring 56 and the wiring 57 have the same thickness.

The wiring 56 includes a wiring 56DH, a wiring 56SL, and a wiring 56C. The wiring 56DH, the wiring 56SL, and the wiring 56C are made of a conductive film in the same layer. Also, the wiring 57 includes a wiring 57GL.

The wiring 56DH is electrically connected to the drain electrode 2D of the semiconductor chip 2. The lower surface 31b of the sealing portion 31 and the surface of the drain electrode 2D of the semiconductor chip 2 are located on the same plane, and the wiring 56DH is formed spanning over the lower surface 31b of the sealing portion 31 and the surface of the drain electrode 2D of the semiconductor chip 2. As illustrated in FIG. 42, the wiring 56DH covers the drain electrode 2D of the semiconductor chip 2 in plan view seen from the side of the lower surface 31b. Note that the plan view corresponds to the case seen on a plane parallel to the upper surface 30a or the lower surface 30b of the substrate 30. No insulating layer is interposed between the drain electrode 2D of the semiconductor chip 2 and the wiring 56DH, and the entire drain electrode 2D of the semiconductor chip 2 is in contact with the wiring 56DH. The wiring 56DH integrally includes a portion in contact with the drain electrode 2D of the semiconductor chip 2, a portion in contact with the lower surface 31b of the sealing portion 31, and a portion in contact with the lead portion 24. Therefore, the lead portion 24 and the drain electrode 2D of the semiconductor chip 2 are electrically connected through the wiring 56DH. As a result, the drain electrode 2D of the semiconductor chip 2 and a part of the wiring 44 formed on the upper surface 1a of the semiconductor device 1 can be electrically connected through the wiring 56DH, the lead portion 24, the wiring 36, and the wiring 40.

The wiring 56SL is electrically connected to the source electrode 3S of the semiconductor chip 3. As illustrated in FIG. 42, the wiring 56SL covers the source electrode 3S of the semiconductor chip 3 in plan view seen from the side of the lower surface 31b. However, the wiring 56SL does not overlap the gate electrode 3G of the semiconductor chip 3 in plan view.

No insulating layer is interposed between the source electrode 3S of the semiconductor chip 3 and the wiring 56SL, and the entire source electrode 3S of the semiconductor chip 3 is in contact with the wiring 56SL. Moreover, the wiring 56SL integrally includes a portion in contact with the source electrode 3S of the semiconductor chip 3, a portion in contact with the lower surface 31b of the sealing portion 31, and a portion in contact with the lead portion 23. Therefore, the lead portion 23 and the source electrode 3S of the semiconductor chip 3 are electrically connected through the wiring 56SL. As a result, the source electrode 3S of the semiconductor chip 3 and a part of the wiring 44 formed on the upper surface 1a of the semiconductor device 1 can be electrically connected through the wiring 56SL, the lead portion 23, the wiring 36, and the wiring 40.

The wiring 56C is formed on the lower surface of the lead portion 21 and is electrically connected to the lead portion 21. Therefore, the wiring 56C is electrically connected to the electrode 4C of the semiconductor chip 4 through the lead portion 21 and the wiring 36C.

The wiring 57GL is a wiring for electrically connecting the gate electrode 3G of the semiconductor chip 3 and the electrode 4C of the semiconductor chip 4. One end of the wiring 57GL is located on the lower surface of the lead portion (gate connection conductor portion) 22 and is electrically connected to the lead portion 22, and the other end of the wiring 57GL is located on the gate electrode 3G of the semiconductor chip 3 and is electrically connected to the gate electrode 3G. As illustrated in FIG. 42, the wiring 57GL covers the gate electrode 3G of the semiconductor chip 3 in plan view seen from the side of the lower surface 31b. However, the wiring 57GL does not overlap the source electrode 3S of the semiconductor chip 3 in plan view. No insulating layer is interposed between the gate electrode 3G of the semiconductor chip 3 and the wiring 57GL, and the entire gate electrode 3G of the semiconductor chip 3 is in contact with the wiring 57GL. Moreover, the wiring 57GL integrally includes a portion in contact with the gate electrode 3G of the semiconductor chip 3, a portion in contact with the lower surface 31b of the sealing portion 31, and a portion in contact with the lower surface of the lead portion 22.

Therefore, the lead portion 22 and the gate electrode 3G of the semiconductor chip 3 are electrically connected through the wiring 57GL. The gate electrode 2G of the semiconductor chip 2 is electrically connected to the electrode 4C of the semiconductor chip 4 through the wiring 57GL, the lead portion 22, and the above-described wiring 36GL. The thickness of the wiring 57GL is smaller than the thickness of the wiring 56 (56DH, 56SL, and 56C).

The seed layer 51a can also be formed by the sputtering instead of the electroless plating. For example, a titanium (Ti) layer formed by the sputtering can be used as the seed layer 51a.

When the semiconductor chip 4 is mounted directly on the back tape 25 without using the DAF 26, the back surface of the semiconductor chip 4 is exposed on the lower surface 30b of the substrate 30, and thus the seed layer 51a comes into contact with the back surface of the semiconductor chip 4. In other words, the seed layer 51a comes into contact with the semiconductor substrate constituting the semiconductor chip 4. Since copper has a high diffusion coefficient into semiconductor substrates, particularly silicon substrates, if an electroless copper plating layer is formed as the seed layer 51a, there is a concern that copper (Cu) in the seed layer 51a diffuses into the semiconductor substrate constituting the semiconductor chip 4, resulting in the decrease in reliability.

In contrast, when a titanium (Ti) film formed by the sputtering is used as the seed layer 51a, even if the DAF 26 is not used and the seed layer 51a comes into contact with the back surface of the semiconductor chip 4, there is no problem of the diffusion into the semiconductor substrate.

Furthermore, as described above, if the adhesive layer of the back tape 25 rises up onto the side surfaces of the semiconductor chips 2, 3, and 4 when the semiconductor chips 2, 3, and 4 are mounted on the back tape 25, the raised portions of the adhesive layer are not filled with the sealing portion 31, and there is a risk that parts of the side surfaces of the semiconductor chips 2, 3, and 4 are exposed on the lower surface 30b of the substrate 30. When parts of the side surfaces of the semiconductor chips 2, 3, and 4 are exposed on the lower surface 30b of the substrate 30, since the seed layer 51a comes into contact with the exposed part, there is a concern that copper (Cu) is more easily diffused from the seed layer 51a into the semiconductor substrate constituting the semiconductor chip 4 if an electroless copper plating layer is used as the seed layer 51a. In contrast, when a titanium film formed by the sputtering is used as the seed layer 51a, there is no problem of the diffusion into the semiconductor substrate even if a part of the side surface of the semiconductor chip 4 is exposed on the lower surface 30b of the substrate 30. Therefore, when a titanium (Ti) film formed by the sputtering is used as the seed layer 51a, it is permissible that a part of the side surface of the semiconductor chip 4 is exposed on the lower surface 30b of the substrate 30. This provides a solution to the problem of insufficient filling of the sealing resin.

Alternatively, the problem can be solved by thickening the surfaces of the semiconductor chips 2, 3, and 4 that face the back tape 25. For example, a plating film of copper or the like is increased on the drain electrode 2D of the semiconductor chip 2 and on the gate electrode 3G and the source electrode 3S of the semiconductor chip 3, and the DAF 26 having a thickness approximately the same as that of the plating film is formed on the back surface of the semiconductor chip 4. The adhesive layer of the back tape 25 has a thickness of approximately 1 to 5 m depending on the type of back tape, and by providing the increased plating film and the DAF 26 so as to be thicker than the adhesive layer of the back tape 25, it is possible to prevent the electroless copper plating layer (seed layer 51a) from reaching the side surfaces of the semiconductor chips 2, 3, and 4 even if regions where the sealing portion 31 is not filled are generated.

In addition, it is also possible to perform the step of forming the wiring (here, wirings 56 and 57) on the side of the lower surface 30b of the substrate 30 together (simultaneously) with the step of forming the wiring (any of wirings 36, 40, and 44) on the side of the upper surface 30a of the substrate 30. This makes it possible to reduce the number of manufacturing steps of the semiconductor device.

Next, as illustrated in FIG. 43 and FIG. 44, an insulating layer 59 is formed on the lower surface 30b of the substrate 30 so as to cover the wirings 56 and 57. The insulating layer 59 is made of an insulating resin material such as a thermosetting resin. In FIG. 43 and FIG. 44 and the following drawings, for simplification, the seed layer 51a, the metal layer 51b, and the metal layer 51c constituting the wiring 56 are not illustrated separately but are illustrated integrally, and the seed layer 51a and the metal layer 51b constituting the wiring 57 are not illustrated separately but are illustrated integrally.

Next, as illustrated in FIG. 45 and FIG. 46, the insulating layer 59 is polished to reduce the thickness thereof. At this time, a lower surface 59b of the insulating layer 59 is polished until the lower surface of the wiring 56 is exposed from the lower surface 59b of the insulating layer 59. In this way, when the polishing of the insulating layer 59 is finished, the lower surface of the wiring 56 is exposed from the lower surfaces 59b of the insulating layer 59. Since the wiring 57 is thinner than the wiring 56, the state in which the wiring 57 is covered with the insulating layer 59 is maintained even after polishing of the insulating layer 59 is finished. Therefore, the lower surface of the wiring 56 (56C, 56DH, and 56SL) is exposed from the lower surface 59b of the insulating layer 59, but the wiring 57 (57GL) is not exposed from the lower surface 59b of the insulating layer 59. Note that the lower surface 59b of the insulating layer 59 is the surface opposite to the side where the insulating layer 59 is in contact with (faces) the lower surface 30b of the substrate 30.

Note that it is also possible to form a plating layer (for example, a gold plating layer) on the lower surface of the wiring 56 exposed from the lower surface 59b of the insulating layer 59 if necessary.

Thereafter, adjacent semiconductor packages are separated by cutting using a dicing blade or the like, whereby the semiconductor device 1 illustrated in FIG. 47 to FIG. 50 can be obtained. Note that FIG. 50 is a bottom view of the semiconductor device 1.

The semiconductor device 1 according to this embodiment includes the substrate 30 in which the semiconductor chips 2, 3, and 4 are sealed, the wiring structure formed on the upper surface 30a of the substrate 30, and the wiring structure formed on the lower surface 30b of the substrate 30. The wiring structure formed on the upper surface 30a of the substrate 30 is made up of the wirings 36, 40, and 44 and the insulating layers 37 and 42 described above. The wiring structure formed on the lower surface 30b of the substrate 30 is made up of the wirings 56 and 57 and the insulating layer 59 described above. Specifically, the wirings 56 and 57 and the insulating layer 59 are formed on the lower surface 30b of the substrate 30. In plan view, the wiring 56 (56C, 56DH, and 56SL) is surrounded by the insulating layer 59 but does not overlap the insulating layer 59. On the other hand, the wiring 57 (57GL) is thinner than the wiring 56 (56C, 56DH, and 56SL) and is covered with the insulating layer 59. The substrate 30 includes the semiconductor chips 2, 3, and 4, the lead portions 21, 22, 23, and 24, and the sealing portion 31 that seals them.

The lower surface 1b of the semiconductor device 1 is made up of the lower surface 59b of the insulating layer 59 and the lower surface of the wiring 56. The lower surface of the wiring 56 is exposed on the lower surface 1b of the semiconductor device 1, and the exposed portion (lower surface) of the wiring 56 can function as an external terminal (external connection terminal) of the semiconductor device 1. In other words, the wiring 56 (56C, 56DH, and 56SL) exposed from the insulating layer 59 can function as an external terminal.

The wiring 56C exposed on the lower surface 1b of the semiconductor device 1 (that is, the wiring 56C exposed from the insulating layer 59) is electrically connected to the electrode 4C of the semiconductor chip 4 through the lead portion 21 and the wiring 36C, and thus can function as the terminal T4 described above (see FIG. 1).

The wiring 56DH exposed on the lower surface 1b of the semiconductor device 1 (that is, the wiring 56DH exposed from the insulating layer 59) is electrically connected to the drain electrode 2D of the semiconductor chip 2, and thus can function as the terminal T1 (see FIG. 1).

The wiring 56SL exposed on the lower surface 1b of the semiconductor device 1 (that is, the wiring 56SL exposed from the insulating layer 59) is electrically connected to the source electrode 3S of the semiconductor chip 3, and thus can function as the terminal T2 (see FIG. 1).

In addition, the terminal T3 (see FIG. 1) may be formed from the wiring 56 exposed on the lower surface 1b of the semiconductor device 1 or may be formed from the wiring 44 exposed on the upper surface 1a of the semiconductor device 1, and is electrically connected to the wiring 36DS in any case.

In the semiconductor device 1 according to this embodiment, the wiring structure formed on the upper surface 30a of the substrate 30 includes three layers of wiring (wiring layers), but it is sufficient that the number of layers is at least one, and the number may also be four or more.

When mounting the semiconductor device 1 on the wiring board, the semiconductor device 1 is mounted on the wiring board such that the lower surface 1b of the semiconductor device 1 faces the wiring board, and the wiring 56, which is the external terminal of the semiconductor device 1, is electrically connected to the terminal of the wiring board via a conductive bonding material such as solder. At that time, electronic components such as coils can also be mounted on the upper surface 1a of the semiconductor device 1. In this case, the electrodes of the electronic components are electrically connected to the wiring 44 on the upper surface 1a of the semiconductor device 1 via a conductive bonding material such as solder. Furthermore, if no electronic component is mounted on the upper surface 1a of the semiconductor device 1, the formation of the wiring 44 can be omitted.

### <Main Features and Effects>

The inventor of this application has been studying a semiconductor device (semiconductor package) including a semiconductor chip for switching (here, semiconductor chips 2 and 3). The semiconductor chip for switching has a front electrode and a back electrode located on the opposite sides to each other, and a large current flows between the front electrode (here, source electrodes 2S and 3S) and the back electrode (here, drain electrodes 2D and 3D). In such a semiconductor device, an external terminal (here, wirings 56DH and 56SL) that is electrically connected to the front electrode or the back electrode of the semiconductor chip for switching is provided, and it is important to electrically connect the external terminal and the front electrode or the back electrode of the semiconductor chip for switching at a low resistance. This is because if a connection resistance between the front electrode or the back electrode of the semiconductor chip for switching and the external terminal is high, the on-resistance may increase, which leads to the degradation of the performance of the semiconductor device including the semiconductor chip for switching.

In the semiconductor device 1 according to this embodiment, the wiring 56DH electrically connected to the drain electrode 2D of the semiconductor chip 2 is formed on the lower surface 30b of the substrate 30 in which the semiconductor chip 2 having the drain electrode 2D serving as a back electrode is sealed with the sealing portion 31. The drain electrode 2D (back electrode) of the semiconductor chip 2 is exposed on the lower surface 30b of the substrate 30, and the wiring 56DH is formed spanning over the sealing portion 31 and the drain electrode 2D of the semiconductor chip 2.

In this embodiment, the wiring 56DH is in contact with the entire drain electrode 2D (back electrode) of the semiconductor chip 2. Therefore, no insulator (insulating layer) is interposed between the wiring 56DH and the drain electrode 2D of the semiconductor chip 2.

The case in which an insulating layer is interposed between the drain electrode 2D (back electrode) of the semiconductor chip 2 and the wiring 56DH unlike this embodiment is assumed, and this case is referred to as a first studied example. In the case of the first studied example, in order to electrically connect the drain electrode 2D of the semiconductor chip 2 and the wiring 56DH, it is necessary to form an opening in the insulating layer on the drain electrode 2D by laser processing or the like and electrically connect the drain electrode 2D of the semiconductor chip 2 and the wiring 56DH through this opening. However, in this case, it is only a part of the drain electrode 2D of the semiconductor chip 2 that is exposed from the opening in the insulating layer, and the drain electrode 2D of the semiconductor chip 2 and the wiring 56DH are electrically connected through the part of the drain electrode 2D exposed from the opening in the insulating layer. For this reason, in the case of the first studied example, there is a concern that the connection resistance between the drain electrode 2D of the semiconductor chip 2 and the wiring 56DH becomes high. In addition, the heat generated in the semiconductor chip 2 is conducted from the drain electrode 2D to the wiring 56DH and dissipated from the wiring 56DH to the wiring board on which it is mounted, but there is a risk that the resistance of the heat conduction (thermal resistance) from the drain electrode 2D of the semiconductor chip 2 to the wiring 56DH also becomes high. Furthermore, if an attempt is made to increase the area of the opening in the insulating layer in order to suppress the resistance, the load of the laser processing increases, which leads to the decrease in the productivity of the semiconductor device. Moreover, since there is a limit to how much the area of the opening in the insulating layer can be increased to suppress resistance, it is not easy to reduce the connection resistance between the drain electrode 2D of the semiconductor chip 2 and the wiring 56DH in the case of the first studied example.

In contrast, in this embodiment, no insulator (insulating layer) is interposed between the wiring 56DH and the drain electrode 2D of the semiconductor chip 2, and the wiring 56DH is in contact with the entire drain electrode 2D (back electrode) of the semiconductor chip 2.

Therefore, in this embodiment, it is possible to reduce the connection resistance (electrical resistance) between the drain electrode 2D of the semiconductor chip 2 and the wiring 56DH. As a result, the on-resistance (conduction resistance when the power MOSFET 12 in the semiconductor chip 2 is turned on) can be suppressed, and the performance of the semiconductor device can be improved. In addition, since the resistance of heat conduction (thermal resistance) from the drain electrode 2D of the semiconductor chip 2 to the wiring 56DH can also be suppressed, the heat dissipation characteristics of the semiconductor device can be improved, and the performance of the semiconductor device can be improved also in this respect.

Also, in this embodiment, since no insulator (insulating layer) is interposed between the wiring 56DH and the drain electrode 2D of the semiconductor chip 2, the thickness of the semiconductor device can be suppressed.

In addition, in this embodiment, no insulating layer is interposed between the drain electrode 2D of the semiconductor chip 2 and the wiring 56DH, and thus a step of forming an opening in the insulating layer by laser processing or the like is not required. Therefore, it is possible to simplify the manufacturing process of the semiconductor device.

Furthermore, in this embodiment, the source electrode 3S of the semiconductor chip 3 is exposed on the lower surface 30b of the substrate 30, and the wiring 56SL electrically connected to the source electrode 3S of the semiconductor chip 3 is formed on the lower surface 30b of the substrate 30. The wiring 56SL is formed spanning over the sealing portion 31, the source electrode 3S of the semiconductor chip 3, and the surface protective film of the semiconductor chip 3.

In this embodiment, the wiring 56SL is in contact with the entire source electrode 3S of the semiconductor chip 3. Therefore, no insulator (insulating layer) is interposed between the wiring 56SL and the source electrode 3S of the semiconductor chip 3. In this embodiment, since the wiring 56SL is in contact with the entire source electrode 3S of the semiconductor chip 3, it is possible to reduce the connection resistance (electrical resistance) between the source electrode 3S of the semiconductor chip 3 and the wiring 56SL. As a result, the on-resistance (conduction resistance when the power MOSFET 13 in the semiconductor chip 3 is turned on) can be suppressed, and the performance of the semiconductor device can be improved.

Furthermore, in this embodiment, the manufacturing process of the semiconductor device is devised such that no insulator (insulating layer) is interposed between the wiring 56DH and the drain electrode 2D of the semiconductor chip 2 and the wiring 56DH can be in contact with the entire drain electrode 2D (back electrode) of the semiconductor chip 2.

In this embodiment, for manufacturing the semiconductor device, first, the lead frame 20 having the lead portions 21, 22, 23, and 24 and the semiconductor chips 2, 3, and 4 are disposed on the back tape 25 (sheet member) (see FIG. 7 to FIG. 10). At this time, the semiconductor chip 2 is disposed on the back tape 25 such that the drain electrode 2D (back electrode) of the semiconductor chip 2 faces the back tape 25. Then, the sealing portion 31 for sealing the semiconductor chips 2, 3, and 4 and the lead portions 21, 22, 23, and 24 is formed on the back tape 25 (see FIG. 11 and FIG. 12). Next, the back tape 25 is peeled off from the sealing portion 31 (substrate 30) (see FIG. 17 to FIG. 20), and then the wiring 56DH electrically connected to the drain electrode 2D of the semiconductor chip 2 is formed on the side of the lower surface 31b of the sealing portion 31 (that is, on the side of the lower surface 30b of the substrate 30) (see FIG. 33 to FIG. 42).

After the semiconductor chip 2 is disposed on the back tape 25 such that the drain electrode 2D of the semiconductor chip 2 faces the back tape 25, the sealing portion 31 is formed on the back tape 25. Therefore, when the back tape 25 is peeled off from the sealing portion 31 (substrate 30), the entire drain electrode 2D of the semiconductor chip 2 is exposed on the side of the lower surface 31b of the sealing portion 31 (that is, on the side of the lower surface 30b of the substrate 30). Then, in the state where the entire drain electrode 2D of the semiconductor chip 2 is exposed on the side of the lower surface 31b of the sealing portion 31 (that is, on the side of the lower surface 30b of the substrate 30), the wiring 56DH having the shape and size that cover the drain electrode 2D of the semiconductor chip 2 in plan view is formed, so that the wiring 56DH is in contact with the entire drain electrode 2D of the semiconductor chip 2. Therefore, the structure in which the entire drain electrode 2D of the semiconductor chip 2 is in contact with the wiring 56DH can be easily and accurately obtained.

In addition, in this embodiment, the semiconductor chip 3 is disposed on the back tape 25 such that the gate electrode 3G and the source electrode 3S of the semiconductor chip 3 face the back tape 25, and then the sealing portion 31 is formed on the back tape 25. Therefore, when the back tape 25 is peeled off from the sealing portion 31 (substrate 30), the entire source electrode 3S of the semiconductor chip 3 is exposed on the side of the lower surface 31b of the sealing portion 31 (that is, on the side of the lower surface 30b of the substrate 30). Then, in the state where the entire source electrode 3S of the semiconductor chip 3 is exposed on the side of the lower surface 31b of the sealing portion 31 (that is, on the side of the lower surface 30b of the substrate 30), the wiring 56SL having the shape and size that cover the source electrode 3S of the semiconductor chip 3 in plan view is formed, so that the wiring 56SL is in contact with the entire source electrode 3S of the semiconductor chip 3. Therefore, the structure in which the entire source electrode 3S of the semiconductor chip 3 is in contact with the wiring 56SL can be easily and accurately obtained.

Also, in this embodiment, since the source electrode 2S of the semiconductor chip 2 and the drain electrode 3D of the semiconductor chip 3 are electrically connected by the wiring 36DS formed by plating, a degree of freedom in the wiring width is high, and the source electrode 2S of the semiconductor chip 2 and the drain electrode 3D of the semiconductor chip 3 can be connected in the shortest path. This makes it easier to achieve low impedance and low on-resistance in the semiconductor device. Therefore, the performance of the semiconductor device can be improved.

In addition, since not only the semiconductor chips 2 and 3 but also the semiconductor chip 4 that controls them is packaged together into a single semiconductor device, the number of semiconductor devices required to configure a desired circuit can be reduced compared with the case in which the semiconductor chip 4 is packaged separately.

Furthermore, the gate electrode 2G of the semiconductor chip 2 can be electrically connected to the electrode 4C of the semiconductor chip 4 by using the wiring 36GH on the side of the upper surface 31a of the sealing portion 31 (that is, on the side of the upper surface 30a of the substrate 30). In addition, the gate electrode 3G of the semiconductor chip 3 can be electrically connected to the electrode 4C of the semiconductor chip 4 by using the wiring 57GL on the side of the lower surface 31b of the sealing portion 31 (that is, on the side of the lower surface 30b of the substrate 30), the lead portion 22 sealed with the sealing portion 31, and the wiring 36GL on the side of the upper surface 31a of the sealing portion 31 (that is, on the side of the upper surface 30a of the substrate 30). Moreover, the lead portion 21 can be electrically connected to the electrodes 4C of the semiconductor chip 4 by using the wiring 36C on the side of the upper surface 31a of the sealing portion 31 (that is, on the side of the upper surface 30a of the substrate 30). In this way, in the semiconductor device, members to be electrically connected can be electrically connected by using the wirings 36, 40, and 44 formed on the side of the upper surface 31a of the sealing portion 31 (that is, on the side of the upper surface 30a of the substrate 30) and the wirings 56 and 57 formed on the side of the lower surface 31b of the sealing portion 31 (that is, on the side of the lower surface 30b of the substrate 30). Since wirings are used instead of a metal plate or wire, less space is required for electrical connections, and the semiconductor device can be reduced in size (reduced in area). Also, the layout design of each component of the semiconductor device becomes easier. Furthermore, the manufacturing cost of the semiconductor device can be reduced.

### Second Embodiment

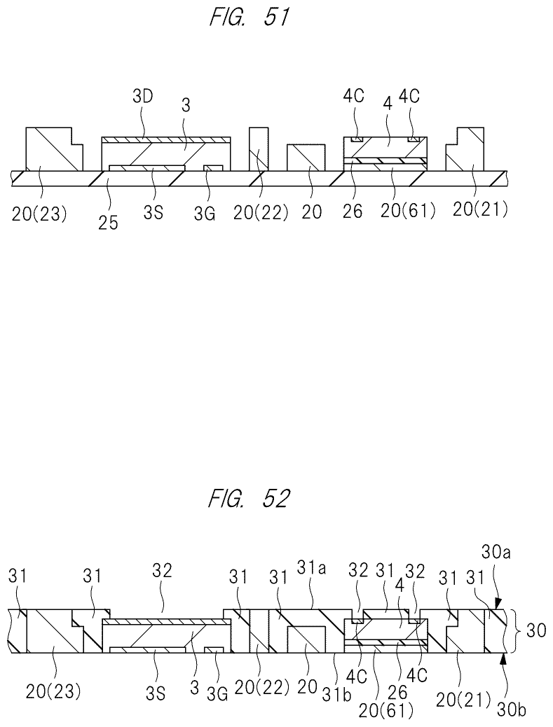

The semiconductor device 1 according to the second embodiment is a modification of the semiconductor device 1 according to the first embodiment described above. FIG. 51 to FIG. 53 are cross-sectional views illustrating the manufacturing process of the semiconductor device 1 according to the second embodiment, and are cross-sectional views at the position corresponding to the above-mentioned line A1-A1.

In the following, the differences between the second embodiment and the first embodiment will be described, and the repetitive description of the same parts as those in the first embodiment will be omitted.

FIG. 51 is a cross-sectional view at the same process stage as that of FIG. 7 to FIG. 9 above. As can be seen by comparing FIG. 51 with FIG. 8 above, the lead frame 20 further includes a die pad (semiconductor chip mounting portion) 61 for mounting the semiconductor chip 4 thereon in the second embodiment (FIG. 51). Then, the semiconductor chip 4 is fixed, via the DAF 26, onto the die pad 61 of the lead frame 20 disposed on the back tape 25. The thickness of the die pad 61 is smaller than those of the lead portions 21, 22, 23, and 24. The semiconductor chip 4 and the die pad 61 are electrically insulated from each other by an insulating bonding material (here, DAF 26) interposed therebetween.

FIG. 52 is a cross-sectional view at the same process stage as that of FIG. 17 to FIG. 19 above. As can be seen by comparing FIG. 52 with FIG. 17 above, when the back tape 25 is peeled off from the lower surface 30b of the substrate 30, the lower surface of the die pad 61 is exposed on the lower surface 30b of the substrate 30 in the second embodiment (FIG. 52). Instead, the DAF 26 and the semiconductor chip 4 are not exposed on the lower surface 30b of the substrate 30.

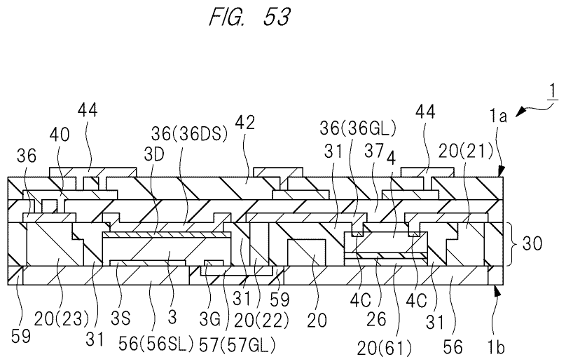

FIG. 53 is a cross-sectional view at the same process stage as that of FIG. 47 to FIG. 49 above. As can be seen by comparing FIG. 53 with FIG. 47 above, the wiring 56 may be formed also on the lower surface of the die pad 61 exposed on the lower surface 30b of the substrate 30 in the second embodiment (FIG. 53).

If the back tape 25 is bent and deformed during the thermal curing process of the sealing resin or the like in the manufacturing process of the semiconductor device, the positions of the semiconductor chips 2, 3, and 4 disposed on the back tape 25 may be displaced, which may cause the connection failure between the wiring and each electrode. For this reason, it is desirable to prevent the back tape 25 from being bent and deformed as much as possible during the manufacturing process of the semiconductor device. As the area of the back tape 25 on which the lead frame 20 is not disposed becomes smaller, the back tape 25 is less likely to be bent and deformed. In the case of the second embodiment, since the lead frame 20 includes the die pad 61, it is easier to prevent the back tape 25 from being bent and deformed. Therefore, it is possible to suppress the connection failure in the semiconductor device.

Furthermore, in the second embodiment, since the die pad 61 and wiring 56 are present under the semiconductor chip 4, the heat generated in the semiconductor chip 4 can be conducted through the DAF 26 and the die pad 61 to the wiring 56 under the die pad 61, and can be dissipated therefrom to the wiring board on which the semiconductor device 1 is mounted. In this way, since the heat generated in the semiconductor chip 4 can be easily dissipated to the outside of the semiconductor device 1, the heat dissipation characteristics of the semiconductor device 1 can be further improved.

Also, in the case of the second embodiment, since the semiconductor chip 4 is not mounted directly on the back tape 25, there is no concern that the adhesive layer of the back tape 25 rises up onto the side surfaces of the semiconductor chip 4 when the semiconductor chip 4 is mounted.

On the other hand, since the die pad 61 has a thickness, the thickness of the semiconductor chip 4 needs to be reduced in the case of the second embodiment. This increases the difficulty of handling the semiconductor chip 4, and the first embodiment is more advantageous than the second embodiment in this respect.

The invention made by the inventor of this application has been specifically described above based on the embodiments thereof, but it goes without saying that the present invention is not limited to the above embodiments, and can be modified in various ways within the range not departing from the gist thereof.

While the present disclosure has been illustrated and described with respect to a particular embodiment thereof, it should be appreciated by those of ordinary skill in the art that various modifications to this disclosure may be made without departing from the spirit and scope of the present disclosure.

1. A semiconductor device comprising:
a substrate including a first semiconductor chip, a second semiconductor chip a plurality of lead portions, and a sealing portion that seals them; and
a first drain wiring, a first source wiring, a first gate wiring, a second source wiring, a second gate wiring, and a third gate wiring,
wherein the first semiconductor chip has a first back electrode for a drain, and a first front electrode for a source and a first gate electrode on an opposite side of the first back electrode,
wherein the second semiconductor chip has a second back electrode for a drain, and a second front electrode for a source and a second gate electrode on an opposite side of the second back electrode,
wherein the first back electrode of the first semiconductor chip is exposed from the sealing portion on a first main surface of the substrate
wherein the second back electrode of the second semiconductor chip is exposed from the sealing portion on a second main surface of the substrate on an opposite side of the first main surface,
wherein the first drain wiring is formed on the first main surface of the substrate and is electrically connected to the first back electrode of the first semiconductor chip,
wherein the first source wiring is formed on the second main surface of the substrate and is electrically connected to both the first front electrode of the first semiconductor chip and the second back electrode of the second semiconductor chip,
wherein the first gate wiring is formed on the second main surface of the substrate and is electrically connected to the first gate electrode of the first semiconductor chip,
wherein the second source wiring is formed on the first main surface of the substrate and is electrically connected to the second front electrode of the second semiconductor chip,
wherein the second gate wiring is formed on the first main surface of the substrate and is electrically connected to the second gate electrode of the second semiconductor chip,
wherein the plurality of lead portions includes a lead portion for a gate,
wherein the third gate wiring is formed on the second main surface of the substrate and is electrically connected to the second gate wiring via the lead portion for the gate, and
wherein on a side of the first main surface of the substrate, the first drain wiring is formed spanning over the first back electrode of the first semiconductor chip and the sealing portion, and is in contact with the entire first back electrode of the first semiconductor chip.

2. The semiconductor device according to claim 1,
wherein no insulator is interposed between the first drain wiring and the first back electrode of the first semiconductor chip.

3. The semiconductor device according to claim 1, further comprising a first insulating layer formed on the first main surface of the substrate,
wherein the first drain wiring and the second source wiring are surrounded by the first insulating layer in plan view, and
wherein the first drain wiring and the second source wiring exposed from the first insulating layer each function as an external terminal.

4. (canceled)

5. (canceled)

6. (canceled)

7. The semiconductor device according to claim 3,
wherein the second gate wiring is thinner than the first drain wiring and the second source wiring, and
wherein the second gate wiring is covered with the first insulating layer.

8. The semiconductor device according to claim 1,
wherein the second source wiring is in contact with the entire second front electrode of the second semiconductor chip.

9. The semiconductor device according to claim 1,
wherein the substrate further includes a third semiconductor chip sealed with the sealing portion,
the semiconductor device further comprising a plurality of wirings formed on the second main surface of the substrate and electrically connecting a plurality of electrodes of the third semiconductor chip and the plurality of lead portions, respectively.

10. The semiconductor device according to claim 1,
wherein an increased film by plating is provided on the first back electrode of the first semiconductor chip.

11. A method of manufacturing a semiconductor device comprising:
(a) a step of disposing a lead frame having a plurality of lead portions on a sheet member;
(b) a step of disposing a first semiconductor chip having a first back electrode on the sheet member such that the first back electrode faces the sheet member; and
(c) after the step (a) and the step (b), a step of forming a sealing portion that seals the first semiconductor chip and the plurality of lead portions, on the sheet member, the sealing portion having a first main surface that faces the sheet member and a second main surface on an opposite side of the first main surface;
(d) after the step (c), a step of peeling off the sheet member from the sealing portion; and
(e) after the step (d), a step of forming a first wiring electrically connected to the first back electrode of the first semiconductor chip, on a side of the first main surface of the sealing portion, the first wiring being in contact with the entire first back electrode of the first semiconductor chip.

12. The method of manufacturing the semiconductor device according to claim 11,
wherein the first main surface of the sealing portion and a surface of the first back electrode of the first semiconductor chip are located on the same plane, and
wherein in the step (e), the first wiring is formed spanning over the first main surface of the sealing portion and the surface of the first back electrode of the first semiconductor chip.

13. The method of manufacturing the semiconductor device according to claim 11,
wherein no insulator is interposed between the first wiring and the first back electrode of the first semiconductor chip.

14. The method of manufacturing the semiconductor device according to claim 11, further comprising:
(f) after the step (e), a step of forming a first insulating layer on the first main surface of the sealing portion so as to cover the first wiring; and
(g) after the step (f), a step of polishing the first insulating layer to expose the first wiring,
wherein the first wiring exposed from the first insulating layer functions as an external terminal.

15. The method of manufacturing the semiconductor device according to claim 11,
wherein the first semiconductor chip has a first source electrode and a first gate electrode on an opposite side of the first back electrode, and
wherein the first back electrode is for a drain,
the method further comprising (d1) after the step (d) and before the step (e), a step of forming, on a side of the second main surface of the sealing portion, a first source wiring electrically connected to the first source electrode of the first semiconductor chip and a first gate wiring electrically connected to the first gate electrode of the first semiconductor chip.

16. The method of manufacturing the semiconductor device according to claim 15, further comprising (b2) before the step (c), a step of disposing a second semiconductor chip having a second back electrode for a drain on the sheet member,
wherein the second semiconductor chip has a second source electrode and a second gate electrode on an opposite side of the second back electrode,
wherein in the step (b2), the second semiconductor chip is disposed on the sheet member such that the second source electrode and the second gate electrode face the sheet member, wherein in the step (c), the second semiconductor chip is also sealed with the sealing portion, and
wherein in the step (e), a second source wiring electrically connected to the second source electrode of the second semiconductor chip and a second gate wiring electrically connected to the second gate electrode of the second semiconductor chip are also formed on the side of the first main surface of the sealing portion.

17. The method of manufacturing the semiconductor device according to claim 16,
wherein the second source wiring is in contact with the entire second source electrode of the second semiconductor chip.

18. The method of manufacturing the semiconductor device according to claim 16,
wherein the first source wiring formed in the step (d1) is electrically connected to both the first source electrode of the first semiconductor chip and the second back electrode of the second semiconductor chip.

19. The method of manufacturing the semiconductor device according to claim 16, further comprising:
(f) after the step (e), a step of forming a first insulating layer on the first main surface of the sealing portion so as to cover the first wiring, the second source wiring, and the second gate wiring; and
after the step (f), a step of polishing the first insulating layer to expose the first wiring and the second source wiring,
wherein the second gate wiring is thinner than the first wiring and the second source wiring, and
wherein in the step (g), a state in which the second gate wiring is covered with the first insulating layer is maintained.

20. The method of manufacturing the semiconductor device according to claim 15, further comprising (b1) before the step (c), a step of disposing a third semiconductor chip having a plurality of electrodes on the sheet member,
wherein in the step (c), the third semiconductor chip is also sealed with the sealing portion, and
wherein in the step (d1), a plurality of second wirings electrically connecting the plurality of electrodes of the third semiconductor chip and the plurality of lead portions, respectively, is also formed on the side of the second main surface of the sealing portion.

21. The method of manufacturing the semiconductor device according to claim 11,
wherein in the step (e), a conductive film in the same layer as the first wiring is formed on the plurality of lead portions exposed from the sealing portion.
